(19) United States
(12) Patent Application Publication
(10) Pub. No.: US 2007/0121358 A1
(43) Pub. Date: May 31, 2007

(54) SEMICONDUCTOR INTEGRATED CIRCUIT

(75) Inventors: Makoto HIROTA, Tokyo (JP); Hidekazu KIKUCHI, Tokyo (JP); Sampei MIYAMOTO, Tokyo (JP)

Correspondence Address: GLOBAL IP COUNSELORS, LLP, 1233 20TH STREET, NW, SUITE 700, WASHINGTON, DC, 20036-2680, US

(73) Assignee: OKI ELECTRIC INDUSTRY CO., LTD., Tokyo (JP)

(21) Appl. No.: 11/557,485

(22) Filed: Nov. 7, 2006

(30) Foreign Application Priority Data
Nov. 28, 2005 (JP) 2005-342893

(51) Int. Cl. G11C 19/08

(52) U.S. Cl. 365/1; 327/1

(57) ABSTRACT

This device has a first circuit including a first field effect transistor and a second circuit coupled to a source of the first electric field transistor. The second circuit applies a first source bias voltage, which does not reversely bias between a source and a body of the first field effect transistor, to the first field effect transistor during the operation mode of the first circuit, and applies a second source bias voltage, which reversely biases between the source and the body of the first field effect transistor, to the first field effect transistor during the standby mode of the first circuit. During the standby mode of the first circuit, the leakage current that flows through the first FET is reduced by means of the reverse bias effect produced by applying the second source bias voltage to the source of the first FET.

This application claims priority to Japanese Patent Application No. 2005-342893. The entire disclosure of Japanese Patent Application No. 2005-342893 is hereby incorporated herein by reference.

### BACKGROUND OF THE INVENTION

### Field of the Invention

The present invention relates to a technology for effectively reducing the leakage current in a semiconductor integrated circuit (IC) in the standby mode thereof.

Recently, with spread of sophisticated portable devices, there has been an increasing demand for high-speed and low-power-consumption IC devices more than ever before. In general, power supply voltage reduction has been performed so as to reduce power consumption of an IC comprised of MOS transistors. However, if the power supply voltage is reduced, the operation speed of a MOS transistor will be slower. Therefore, a method for decreasing the threshold voltage of a MOS transistor can be considered as a countermeasure. However, if the threshold voltage is decreased, the leakage current is increased when a MOS transistor is in an off-state. Until now, the consumption current in an IC has been mainly the discharge and charge current during the operation mode of an IC. However, if the power supply voltage is further reduced with miniaturization of an IC in the future, the leakage current will rapidly increase due to the reduction of the threshold voltage. Accordingly, the consumption current of an IC is considerably increased.

As a conventional method for solving the problem, Japan Patent Application Publication JP-A-07-212218 discloses a method that uses a circuitry called “MT-CMOS”, which is comprised of a VDD of a logic gate comprised of a low threshold MOS transistor and a high threshold MOS transistor functioning as a switch on the GND side. In this method, the logic gate normally operates during the operation mode of the circuitry if the high threshold MOS transistor functioning as a switch is turned on. On the other hand, the leakage current from the low threshold logic gate is effectively reduced by means of the high threshold MOS transistor functioning as a switch during the standby mode of the circuitry if the high threshold MOS transistor functioning as a switch is turned off.

In addition, Japan Patent Application Publication JP-A-04-53496 discloses a method for controlling the threshold of a MOS transistor by means of a body potential, which is realized by providing a body biasing circuit for controlling the body potential of a MOS transistor that comprises a main circuit. During the operation mode of the circuit, a high-speed operation will be realized by setting the threshold of the MOS transistor of the main circuit to be lower. On the other hand, during the standby mode of the circuit, the leakage current can be reduced by setting the threshold of the MOS transistor in the main circuit to be higher.

Furthermore, Japan Patent Application Publication JP-A-11-214962 discloses circuitry in which a MOS switch comprised of a high threshold MOS transistor and a diode are coupled to a VDD side and a GND side of an internal circuit comprised of a low threshold MOS transistor to be disposed in parallel with each other. Normally, this diode is comprised of a MOS diode. In this configuration example, during the standby mode of the circuitry, the source of the internal circuit is biased at a constant potential by means of the MOS diode. The body potentials of the PMOS transistor and the NMOS transistor, both of which comprise the internal circuit, are coupled to a VDD and a GND, respectively. Therefore, if a reverse bias voltage is applied between the body and the source, the threshold of a MOS transistor in an internal circuit will be higher and thus leakage voltage will be reduced.

However, in the method disclosed in Japan Patent Application Publication JP-A-07-212218, the inside logic gate is shielded from the VDD and GND during the standby mode. Therefore, the potential of each of nodes in the logic gate will be unstable. Accordingly, a problem is caused in which a logic gate cannot be configured in a circuit such as a latch circuit and a memory circuit in which the node state before transition to the operation mode needs to be retained during the standby mode.

In addition, in the method disclosed in Japan Patent Application Publication JP-A-04-53496, the reverse bias is applied between the source and the body, and thus a larger bias voltage is applied between the drain and the body than before the application of bias. Therefore, in a highly miniaturized process, junction leakage current is increased. Accordingly, there is a possibility that the leakage current cannot be reduced during the standby mode by means of this increasing junction leakage.

Furthermore, in the method disclosed in Japan Patent Application Publication JP-A-11-214962, the bias voltage is determined by the threshold voltage of the MOS transistor, that is, the gate-to-source voltage. Therefore, a problem is caused in which it is difficult to set the bias voltage to be an arbitrary value. In particular, in a condition in which the leakage current will be larger because the circuit size of the internal circuit is large, it will be necessary to supersize the MOS diode so as to create a low bias voltage that makes it possible to retain latched data in the internal circuit. In this case, it will be necessary to reserve a large layout area. Furthermore, there is a possibility that the junction leakage current of a MOS diode itself and the gate leakage current will be a problem. In addition, even if miniaturization continues to proceed into the future and voltage is further reduced, it will be necessary to create low source bias voltage. In this regard, there is also possibility that similar problems will be caused.

It is therefore an object of the present invention to provide an IC in which both a reduction in the power supply voltage and a reduction in the leakage current are realized.

### SUMMARY OF THE INVENTION

The semiconductor integrated circuit device in accordance with the present invention comprises a first circuit including a first field effect transistor (first FET), and a second circuit that is electrically coupled to a source of the first electric field transistor, and operates based on a first control signal representing the operation mode and the standby mode of the first circuit. The second circuit applies a first source bias voltage, which does not reversely bias between a source and a body of the first field effect transistor, to the first field effect transistor during the operation mode of the first circuit, and applies a second source bias voltage, which reversely biases between the source and the body of the first field effect transistor, to the first field effect transistor during the standby mode.

According to the IC device in accordance with the present invention, the first circuit can normally operate by applying a bias voltage necessary for the operation of the first circuit to the source of the first FET during the operation mode of the first circuit. On the other hand, during the standby mode of the first circuit, the leakage current that flows through the first FET during the standby mode is reduced by means of the reverse bias effect produced by applying the second source bias voltage, which applies a reverse bias between the source and the body of the first FET, to the source of the first FET. Because of this, the consumption current of the first circuit is reduced.

These and other objects, features, aspects, and advantages of the present invention will become apparent to those skilled in the art from the following detailed description, which, taken in conjunction with the annexed drawings, discloses a preferred embodiment of the present invention.

### BRIEF DESCRIPTION OF THE DRAWINGS

Referring now to the attached drawings which form a part of this original disclosure:

FIG. 1 is an equivalent circuit schematic of an IC in accordance with a first embodiment of the present invention;

FIG. 2 is an equivalent circuit schematic of an IC in accordance with a second embodiment of the present invention;

FIG. 3 is an equivalent circuit schematic of an IC in accordance with a third embodiment of the present invention;

FIG. 4 is an equivalent circuit schematic of an IC in accordance with a fourth embodiment of the present invention;

FIG. 5 is an equivalent circuit schematic of an IC in accordance with a fifth embodiment of the present invention;

FIG. 6 is an equivalent circuit schematic of an IC in accordance with a sixth embodiment of the present invention;

FIG. 7 is an equivalent circuit schematic of an IC in accordance with a seventh embodiment of the present invention;

FIG. 8 is an equivalent circuit schematic of an IC in accordance with an eighth embodiment of the present invention;

FIG. 9 is an equivalent circuit schematic of an IC in accordance with a ninth embodiment of the present invention;

FIG. 10 is a equivalent circuit schematic of an IC in accordance with a tenth embodiment of the present invention;

FIG. 11 is a equivalent circuit schematic of an IC in accordance with an eleventh embodiment of the present invention;

FIG. 12 is a equivalent circuit schematic of an IC in accordance with a twelfth embodiment of the present invention;

FIG. 13 is a equivalent circuit schematic of an IC in accordance with a thirteenth embodiment of the present invention;

FIG. 14 is a equivalent circuit schematic of an IC in accordance with a fourteenth embodiment of the present invention;

FIG. 15 is a schematic showing potentials of nodes in a SRAM memory cell shown in FIG. 14;

FIG. 16 is an equivalent circuit schematic of an IC in accordance with a fifteenth embodiment of the present invention;

FIG. 17 is an equivalent circuit schematic of an IC in accordance with a sixteenth embodiment of the present invention.

### DETAILED DESCRIPTION OF THE PREFERRED EMBODIMENTS

Selected embodiments of the present invention will now be explained with reference to the drawings. It will be apparent to those skilled in the art from this disclosure that the following descriptions of the embodiments of the present invention are provided for illustration only and not for the purpose of limiting the invention as defined by the appended claims and their equivalents.

In the following explanation of the embodiments, the components/members in accordance with an embodiment which correspond to those in accordance with a single or plurality of the preceding embodiment(s), are given the same numerals used in the single or plurality of preceding embodiment(s), and an explanation of these components/members will be thereinafter omitted.

### First Embodiment

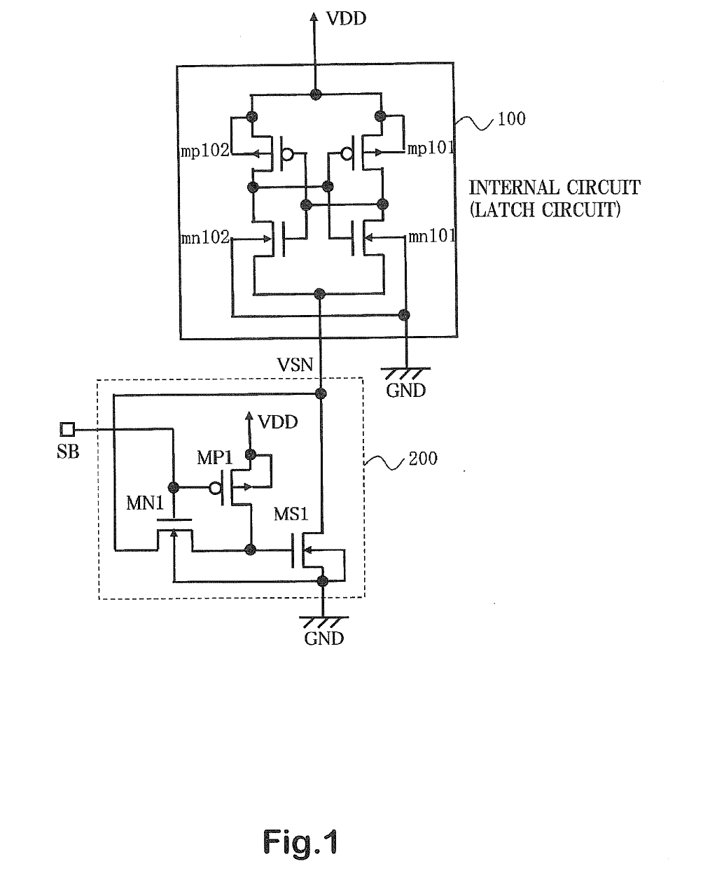

The first embodiment of the present invention provides a semiconductor integrated circuit (IC) for effectively reducing the leakage current in an internal circuit (i.e., a first circuit) and consumption current. FIG. 1 is an equivalent circuit schematic showing a configuration of an IC in accordance with the first embodiment of the present invention.

As shown in FIG. 1, the IC in accordance with the first embodiment of the present invention comprises an internal circuit 100, and a leakage current reducing circuit 200 that is electrically coupled between the internal circuit 100 and a GND and which reduces the leakage current during the standby mode of the internal circuit 100. A sequential circuit or a combinational logic circuit may be used as a typical example of the internal circuit 100. However, the internal circuit 100 is not necessarily limited to these. A flip-flop circuit or a latch circuit can be suggested as a typical example of the sequential circuit. A case in which the internal circuit 100 is comprised of a latch circuit 100 is hereinafter explained as an example.

As shown in FIG. 1, the latch circuit 100 is a heretofore known circuit and comprises of a first PMOS transistor mp101, a second PMOS transistor mp102, a first NMOS transistor mn101, and a second NMOS transistor mn102. The source of the first PMOS transistor mp101 and that of the second PMOS transistor mp102 are coupled to a VDD. The source of the first NMOS transistor mn101 and that of the second NMOS transistor mn102 are coupled to a low side node VSN. The bias potential of the first PMOS transistor mp101 and that of the second PMOS transistor mp102 are retained at VDD. The bias potential of the first NMOS transistor mn101 and that of the second NMOS transistor mn102 are retained at GND. The drain of the first PMOS transistor mp101 and that of the first NMOS transistor mn101 are coupled to each other, and the drains are coupled to the gate of the second PMOS transistor mp102 and that of the second NMOS transistor mn102. The drain of the second PMOS transistor mp102 and that of the second NMOS transistor mn102 are coupled to each other, and the drains are coupled to the gate of the first PMOS transistor mp101 and that of the first NMOS transistor mn101.

The leakage current reducing circuit 200 is coupled to a standby signal terminal SB and the low side node VSN. The leakage current reducing circuit 200 is comprised of a first NMOS switching transistor MS1, a third NMOS transistor MN1, and a third PMOS transistor MP1. The first NMOS switching transistor MS1 is coupled between the low side node VSN and the GND, and is a switching element that connects/disconnects the low side node VSN to/from the GND. The third NMOS transistor MN1 and the third PMOS transistor MP1 configures a control circuit that controls a switching operation of the first NMOS switching transistor MS 1 based on the standby signal terminal SB.

Specifically, as shown in FIG. 1, the source of the first NMOS switching transistor MS1 is coupled to the GND. The drain of the first NMOS switching transistor MS1 is coupled to the low side node VSN. The body of the first NMOS switching transistor MS1 is coupled to the GND. The gate of the first NMOS switching transistor MS1 is coupled to the control circuit that controls a switching operation of the first NMOS switching transistor MS1. The control circuit is comprised of the third NMOS transistor MN1 and the third PMOS transistor MP1. The source of the third NMOS transistor MN1 is coupled to the low side node VSN. The drain of the third NMOS transistor MN1 is coupled to the gate of the first NMOS switching transistor MS1. The gate of the third NMOS transistor MN1 is coupled to the standby signal terminal SB. The body of the third NMOS transistor MN1 is coupled to the GND. The source of the third PMOS transistor MP1 is coupled to the VDD. The drain of the third PMOS transistor MP1 is coupled to the gate of the first NMOS switching transistor MS1. The gate of the third PMOS transistor MP1 is coupled to the standby signal terminal SB. The body of the third PMOS transistor MP1 is coupled to the VDD.

The size of the first NMOS switching transistor MS1, that is, the gate width thereof, is required to be a sufficiently large size, that is, a sufficiently large gate width, so that it influences the properties of the internal circuit 100 during its operation mode as little as possible and is coupled to the GND with an impedance as low as possible. However, a moderate size, that is, a moderate gate width may be used for the first NMOS switching transistor MS1 depending on the relationship between the layout area and the effect of reducing the leakage current of the internal circuit 100.

The operation of the IC in accordance with the present invention will be hereinafter explained.

During the operation mode of the internal circuit 100, a low-level signal Low is output from the standby signal terminal SB, and the third NMOS transistor MN1 is turned off and the third PMOS transistor MP1 is turned on. In addition, the gate potential of the first NMOS switching transistor MS1 will become the same level as that of the VDD, and the first NMOS switching transistor MS1 is turned on. Because of this, the low side node VSN is coupled to the GND with a low impedance. Therefore, the internal circuit 100 normally operates.

During the standby mode of the internal circuit 100, a high-level signal High is output from the standby signal terminal SB, and the third MOS transistor MP1 is turned off and the third NMOS transistor MN1 is turned on. In addition, the gate of the first NMOS switching transistor MS1 is coupled to the low side node VSN. The first NMOS switching transistor MS1 uses the leakage current of the internal circuit 100 during the standby mode as a bias current and operates as with a MOS diode. The first NMOS switching transistor MS1 retains the potential of the low side node VSN at a constant potential that is higher than the GND, such as several hundred mV. The body potentials of the first and second NMOS transistors mn101 and mn102 in the internal circuit 100 are coupled to the GND. Therefore, the leakage current of the first and second NMOS transistors mn101 and mn102 are reduced by means of the reverse bias effect between the source and the body. In addition, the source-to-drain voltage further decreases by means of a bias applied to the low side node VSN, compared to a case in which the low side node VSN is coupled to the GND. Accordingly, the leakage current of the first and second PMOS transistors mp101 and mp102 will be reduced.

As described above, according to the first embodiment of the present invention, the large size first NMOS switching transistor MS1 couples the low side node VSN, to which the sources of the first and second NMOS transistors mn101 and mn102 in the internal circuit 100 are coupled, to the GND at a low impedance during the operation mode of the internal circuit 100. In addition, it biases the sources of the first and second NMOS transistors mn101 and mn102 during the standby mode of the internal circuit 100. Therefore, even if a large leakage current flows through the internal circuit 100, source potentials of the first and second NMOS transistors mn101 and mn102 can be retained at a constant potential without adding a new large size MOS diode. Because of this, even if the internal circuit 100 is configured with a latch circuit or a memory circuit, it is possible to reduce the leakage current while ensuring its data retaining function. In addition, the size of the first NMOS switching transistor MS1 is large. Because of this, it is possible to create a lower source bias voltage of the first and second NMOS transistor mn101 and mn102 than that in a conventional circuit configuration. Accordingly, the present embodiment can also deal with a case in which the voltage of the VDD is decreased in accordance with miniaturization. Furthermore, an additional MOS diode is not necessary because of the generation of the source bias potential. Therefore, an increase of the leakage current caused by the bias circuit can be almost ignored.

### Second Embodiment

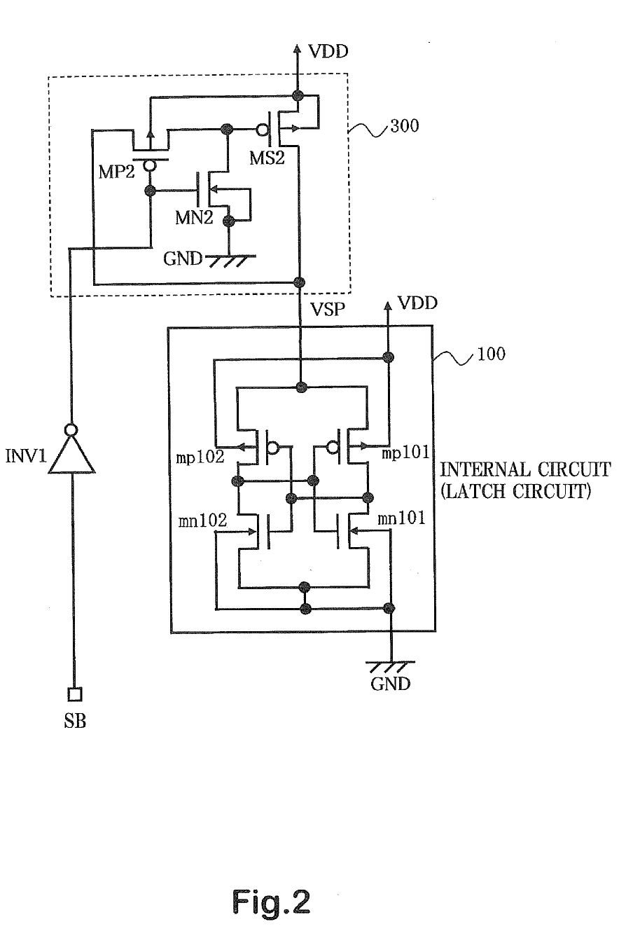

The second embodiment of the present invention provides an IC for effectively reducing the leakage current in an internal circuit and consumption current. FIG. 2 is an equivalent circuit schematic showing a configuration of an IC in accordance with the second embodiment of the present invention.

As shown in FIG. 2, the IC in accordance with the second embodiment of the present invention comprises an internal circuit 100, and a leakage current reducing circuit 300 that is electrically coupled between the internal circuit 100 and a VDD and which reduces the leakage current during the standby mode of the internal circuit 100.

The leakage current reducing circuit 300 is coupled to a standby signal terminal SB through an inverter INV1 and coupled to a high side node VSP. The leakage current reducing circuit 300 is comprised of a second PMOS switching transistor MS2, a fourth NMOS transistor MN2, and a fourth PMOS transistor MP2. The second PMOS switching transistor MS2 is coupled between the high side node VSP and the VDD, and is a switching element that connects/disconnects the high side node VSP to/from the VDD. The fourth NMOS transistor MN2 and the fourth PMOS transistor MP2 configures a control circuit that controls the switching operation of the second PMOS switching transistor MS2 based on an inversion signal of the standby signal terminal SB.

Specifically, as shown in FIG. 2, the source of the second PMOS switching transistor MS2 is coupled to the VDD. The drain of the second PMOS switching transistor MS2 is coupled to the high side node VSP. The body of the second PMOS switching transistor MS2 is coupled to the VDD. The gate of the second PMOS switching transistor MS2 is coupled to a control circuit that controls the switching operation of the second PMOS switching transistor MS2. The control circuit is comprised of a fourth NMOS transistor MN2 and a fourth PMOS transistor MP2. The source of the fourth PMOS transistor MP2 is coupled to the high side node VSP. The drain of the fourth PMOS transistor MP2 is coupled to the gate of the second PMOS switching transistor MS2. The gate of the fourth PMOS transistor MP2 is coupled to the standby signal terminal SB through the inverter INV1. The body of the fourth PMOS transistor MP2 is coupled to the VDD. The source the fourth NMOS transistor MN2 is coupled to the GND. The drain of the fourth NMOS transistor MN2 is coupled to the gate of the second PMOS switching transistor MS2. The gate of the fourth NMOS transistor MN2 is coupled to the standby signal terminal SB through the inverter INV1. The body of the fourth NMOS transistor MN2 is coupled to the GND.

The size of the second PMOS switching transistor MS2, that is, the gate width thereof, is required to be a sufficiently large size, that is, a sufficiently large gate width so that it influences the properties of the internal circuit 100 during its operation mode as little as possible and is coupled to the VDD with an impedance as low as possible. However, a moderate size, that is, a moderate gate width, may be used for the second PMOS switching transistor MS2, depending on the relationship between the layout area and the effect of reducing the leakage current of the internal circuit 100.

The operation of the IC in accordance with the present invention will be hereinafter explained.

During the operation mode of the internal circuit 100, a low-level signal Low is output from the standby signal terminal SB, and a high-level signal High, that is, an inversion signal of the standby signal terminal SB, is input into the leakage current reducing circuit 300. As a result, the fourth NMOS transistor MN2 is turned on and the fourth PMOS transistor MP2 is turned off. In addition, the gate potential of the second PMOS switching transistor MS2 will become the same level as that of the GND, and the second PMOS switching transistor MS2 is turned on. Because of this, the high side node VSP is coupled to the VDD with a low impedance. Therefore, the internal circuit 100 normally operates.

During the standby mode of the internal circuit 100, a high-level signal High is output from the standby signal terminal SB, and a low-level signal Low, that is, an inversion signal of the standby signal terminal SB, is input into the leakage current reducing circuit 300. The fourth PMOS transistor MP2 is turned on and the fourth NMOS transistor MN2 is turned off. Then, the gate of the second PMOS switching transistor MS2 is coupled to the high side node VSP. The second PMOS switching transistor MS2 uses the leakage current of the internal circuit 100 during the standby mode as a bias current and operates as with a MOS diode. The second NMOS switching transistor MS2 retains the potential of the high side node VSP at a constant potential that is lower than the VDD. The body potentials of the first and second PMOS transistors mp101 and mp102 in the internal circuit 100 are coupled to the VDD. Therefore, the leakage current of the first and second PMOS transistors mp101 and mp102 are reduced by means of the reverse bias effect between the source and the body. In addition, the source-to-drain voltage further decreases by means of a bias applied to the high side node VSP, compared to a case in which the high side node VSP is coupled to the VDD. Accordingly, the leakage current of the first and second NMOS transistors mn101 and mn102 will be reduced.

As described above, according to the second embodiment of the present invention, the large size second PMOS switching transistor MS2 couples the high side node VSP, to which the sources of the first and second PMOS transistors mp101 and mp102 in the internal circuit 100 are coupled, to the VDD at a low impedance during the operation mode of the internal circuit 100. In addition, it biases the sources of the first and second PMOS transistors mp101 and mp102 during the standby mode of the internal circuit 100. Therefore, even if a large leakage current flows through the internal circuit 100, the source potentials of the first and second PMOS transistors mp101 and mp102 can be retained at a constant potential without adding a new large size MOS diode. Because of this, even if the internal circuit 100 is configured with a latch circuit or a memory circuit, it is possible to reduce the leakage current while ensuring its data retaining function. In addition, the size of the second PMOS switching transistor MS2 is large. Because of this, it is possible to create a lower source bias voltage of the first and second PMOS transistors mp101 and mp102 than that in a conventional circuit configuration. Accordingly, the present embodiment can also deal with a case in which the voltage of the VDD is decreased in accordance with miniaturization. Furthermore, an additional MOS diode is not necessary because of the generation of the source bias potential. Therefore, an increase of the leakage current caused by the bias circuit can be almost ignored.

### Third Embodiment

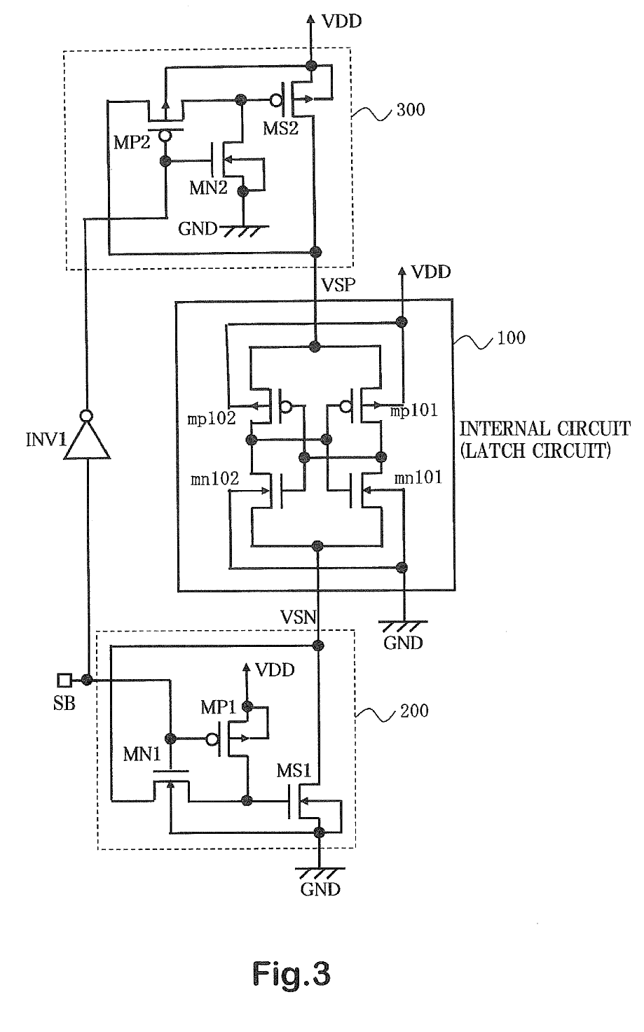

The third embodiment of the present invention provides an IC for effectively reducing the leakage current in an internal circuit and consumption current. FIG. 3 is an equivalent circuit schematic showing a configuration of an IC in accordance with the third embodiment of the present invention.

As shown in FIG. 3, the IC in accordance with the third embodiment of the present invention comprises an internal circuit 100, a leakage current reducing circuit 200 that is electrically coupled between the internal circuit 100 and a GND and which reduces the leakage current during the standby mode of the internal circuit 100, and a leakage current reducing circuit 300 that is electrically coupled between the internal circuit 100 and a VDD and which reduces the leakage current during the standby mode of the internal circuit 100.

In the present embodiment, the operation of the leakage current reducing circuit 200 during the operation mode and the standby mode of the internal circuit 100 is the same as those in accordance with the above described respective embodiments. Therefore, overlapping explanation will be hereinafter omitted. With the circuit configuration in accordance with the present embodiment, the same effects as those in accordance with the above described respective embodiments can be obtained.

### Fourth Embodiment

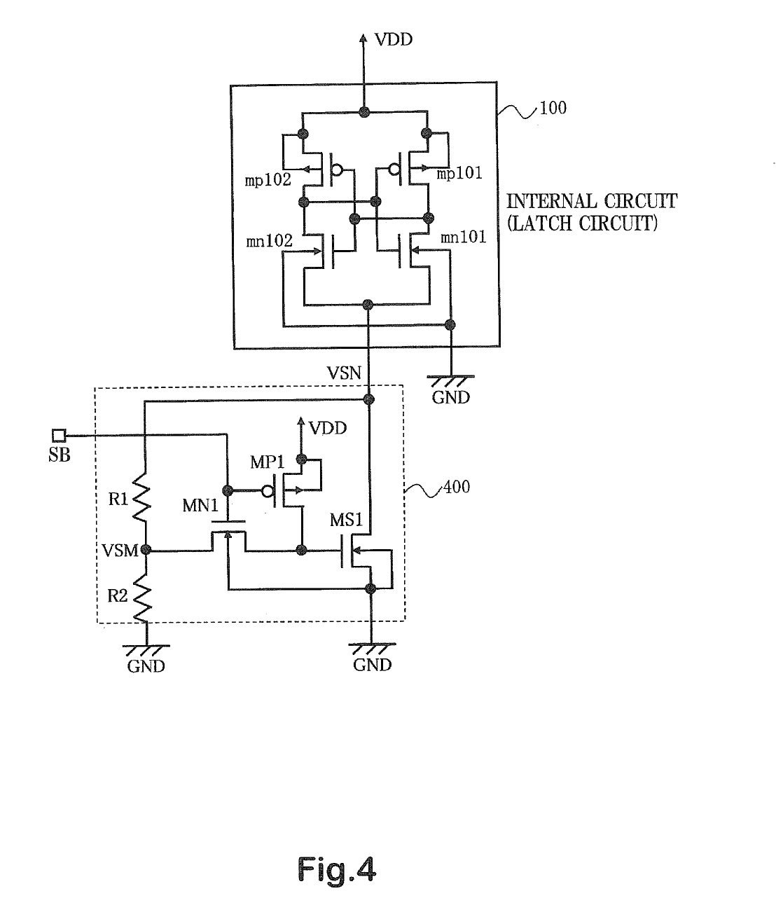

The fourth embodiment of the present invention provides an IC for effectively reducing the leakage current in an internal circuit and consumption current. FIG. 4 is an equivalent circuit schematic showing a configuration of an IC in accordance with the fourth embodiment of the present invention.

As shown in FIG. 4, the IC in accordance with the fourth embodiment of the present invention comprises an internal circuit 100, and a leakage current reducing circuit 400 that is electrically coupled between the internal circuit 100 and a GND and which reduces the leakage current during the standby mode of the internal circuit 100.

The leakage current reducing circuit 400 comprises a control circuit that is different from that in the leakage current reducing circuit 200 in accordance with the first embodiment. In short, the control circuit in accordance with the present embodiment is comprised of a third NMOS transistor MN1, a third PMOS transistor MP1, and a voltage divider comprised of a serial connection of a first resistance R1 and a second resistance R2. The voltage divider comprised of the serial connection of the first resistance R1 and the second resistance R2 is coupled between a low side node VSN and a GND, and a divided voltage determined by the ratio of the first resistance R1 to the second resistance R2 will arise in a node VSM between the first resistance R1 and the second resistance R2.

The source of the third NMOS transistor MN1 is coupled to the node VSM of the voltage divider. In other words, the source of the third NMOS transistor MN1 is coupled to a low side node VSN through the first resistance R1, and at the same time as this, it is coupled to the GND through the second resistance R2. The drain of the third NMOS transistor MN1 is coupled to the gate of a first NMOS switching transistor MS1. The gate of the third NMOS transistor MN1 is coupled to a standby signal terminal SB. The body of the third NMOS transistor MN1 is coupled to the GND. The source of the third PMOS transistor MP1 is coupled to a VDD. The drain of the third PMOS transistor MP1 is coupled to the gate of the first NMOS switching transistor MS1. The gate of the third PMOS transistor MP1 is coupled to the standby signal terminal SB. The body of the third PMOS transistor MP1 is coupled to the VDD.

The size of the first NMOS switching transistor MS1, that is, the gate width thereof, is required to be a sufficiently large size, that is, a sufficiently large gate width so that it influences the properties of the internal circuit 100 during its operation mode as little as possible and is coupled to the GND with an impedance as low as possible. However, a moderate size, that is, a moderate gate width may be used for the first NMOS switching transistor MS1 depending on a relationship between the layout area and an effect of reducing the leakage current of the internal circuit 100. However, the size of the first NMOS switching transistor MS1 may be limited by the properties of the internal circuit during the operation mode. In other words, the potential of the low side node VSN is determined by the size and the leakage current of the internal circuit 100 during the standby mode. Therefore, it may be difficult for the potential of the low side node VSN to be set to be an arbitrary value. Accordingly, the gate potential of the first NMOS switching transistor MS1 is controlled by the potential of the node VSM determined by the ratio of the voltage derived by the ratio of the first resistance R1 to the second resistance R2.

The operation of the IC in accordance with the present invention will be hereinafter explained.

During the operation mode of the internal circuit 100, a low-level signal Low is output from the standby signal terminal SB, and the third NMOS transistor MN1 is turned off and the third PMOS transistor MP1 is turned on. In addition, the gate potential of the first NMOS switching transistor MS1 will become the same level as the VDD, and the first NMOS switching transistor MS1 is turned on. Because of this, the low side node VSN is coupled to the GND with a low impedance. Therefore, the internal circuit 100 normally operates.

During the standby mode of the internal circuit 100, a high-level signal High is output from the standby signal terminal SB, and the third PMOS transistor MP1 is turned off and the third NMOS transistor MN1 is turned on. In addition, the gate of the first NMOS switching transistor MS1 is coupled to a potential that is determined by the ratio of the voltage derived by the ratio of the first resistance R1 to the second resistance R2 and will arise in the node VSM. The first NMOS switching transistor MS1 uses the leakage current of the internal circuit 100 during the standby mode as a bias current and operates as with a MOS diode. The first NMOS switching transistor MS1 retains the potential of the low side node VSN at a constant potential that is higher than the GND. The body potentials of the first and second NMOS transistors mn101 and mn102 in the internal circuit 100 are coupled to the GND. Therefore, the leakage current of the first and second NMOS transistors mn101 and mn102 are reduced by means of the reverse bias effect between the source and the body. In addition, the source-to-drain voltage further decreases by means of a bias applied to the low side node VSN, compared to a case in which the low side node VSN is coupled to the GND. Accordingly, the leakage current of the first and second PMOS transistors mp101 and mp102 will be reduced.

As described above, according to the fourth embodiment of the present invention, it will be possible to adjust the potential of the low side node VSN by adjusting the ratio of the first resistance R1 to the second resistance R2.

In addition, a corrective effect can be obtained in which a source bias voltage will be higher on condition that the leakage current of the internal circuit 100 is large, and the source bias voltage will be lower on condition that the leakage current of the internal circuit 100 is small, by controlling the gate potential of the first NMOS switching transistor MS1 by means of the ratio of the first resistance R1 to the second resistance R2. The condition in which the leakage current is small is one in which the threshold voltage of the MOS transistor in the internal circuit 100 is large. Therefore, the condition will be one in which the minimum operation voltage necessary for ensuring a data retaining operation by the internal circuit during the standby mode is high. Because of this, when the bias current is small, the condition that the bias voltage is small has the effect of enhancing the noise resistance of the data retaining operation.

### Fifth Embodiment

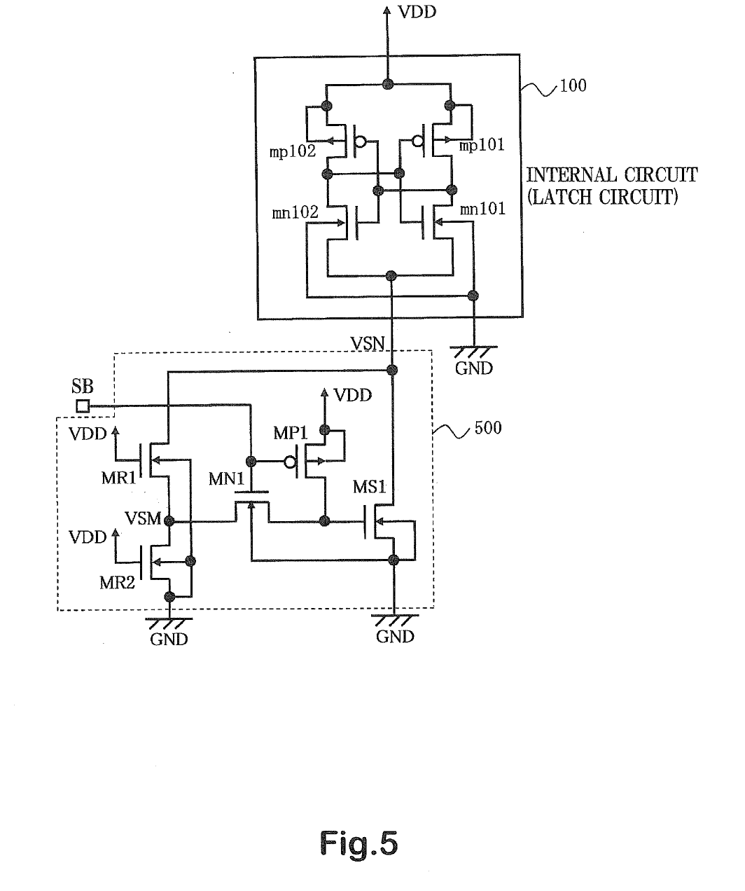

The fifth embodiment of the present invention provides an IC for effectively reducing the leakage current in an internal circuit and consumption current. FIG. 5 is an equivalent circuit schematic showing a configuration of an IC in accordance with the fifth embodiment of the present invention.

As shown in FIG. 5, the IC in accordance with the fifth embodiment of the present invention comprises an internal circuit 100, and a leakage current reducing circuit 500 that is electrically coupled between the internal circuit 100 and a GND and which reduces the leakage current during the standby mode of the internal circuit 100.

The leakage current reducing circuit 500 is coupled to a standby signal terminal SB and a low side node VSN. The leakage current reducing circuit 500 is comprised of a first NMOS switching transistor MS1, a third NMOS transistor MN1, a third PMOS transistor MP1, and a voltage divider that is comprised of a serial connection of a fifth NMOS transistor MR1 that is always in an on-state and a sixth NMOS transistor MR2 that is always in an on-state. The first NMOS switching transistor MS1 is coupled between the low side node VSN and the GND, and is a switching element that connects/disconnects the low side node VSN to/from the GND. The third NMOS transistor MN1, the third PMOS transistor MP1, and the voltage divider that is comprised of a serial connection of the fifth NMOS transistor MR1 that is always in the on-state and the sixth NMOS transistor MR2 that is always in the on-state comprises a control circuit that controls the switching operation of the first NMOS switching transistor MS1 based on the standby signal terminal SB.

As shown in FIG. 5, this control circuit is comprised of the third NMOS transistor MN1, the third PMOS transistor MP1, and the voltage divider that is comprised of the serial connection of the fifth NMOS transistor MR1 that is always in the on-state and the sixth NMOS transistor MR2 that is always in the on-state. The voltage divider comprised of the serial connection of the fifth NMOS transistor MR1 that is always in the on-state and the sixth NMOS transistor MR2 that is always in the on-state is coupled between the low side node VSN and the GND, and the divided voltage determined by the ratio of a first on-resistance of the fifth NMOS transistor MR1 to a second on-resistance of the sixth NMOS transistor MR2 will arise in a node VSM between the fifth NMOS transistor MR1 and the sixth NMOS transistor MR2. Here, the gate of the fifth NMOS transistor MR1 may be coupled to the VDD so as to keep the fifth NMOS transistor MR1 to be always in the on-state. In the same way, the gate of the sixth NMOS transistor MR2 may be coupled to the VDD so as to keep the sixth NMOS transistor MR2 to be always in the on-state.

The configuration of the leakage current reducing circuit 500 is the same as that of the leakage current reducing circuit 400 described in the fourth embodiment (see FIG. 4) except for the fifth NMOS transistor MR1 and the sixth NMOS transistor MR2. Therefore, the operation associated with the voltage divider in the fifth embodiment is the same as that in the fourth embodiment. Therefore, the operation of the IC in accordance with the present embodiment will be hereinafter omitted. With the fifth embodiment of the present invention, the same effects as those in accordance with the fourth embodiment can be obtained.

### Sixth Embodiment

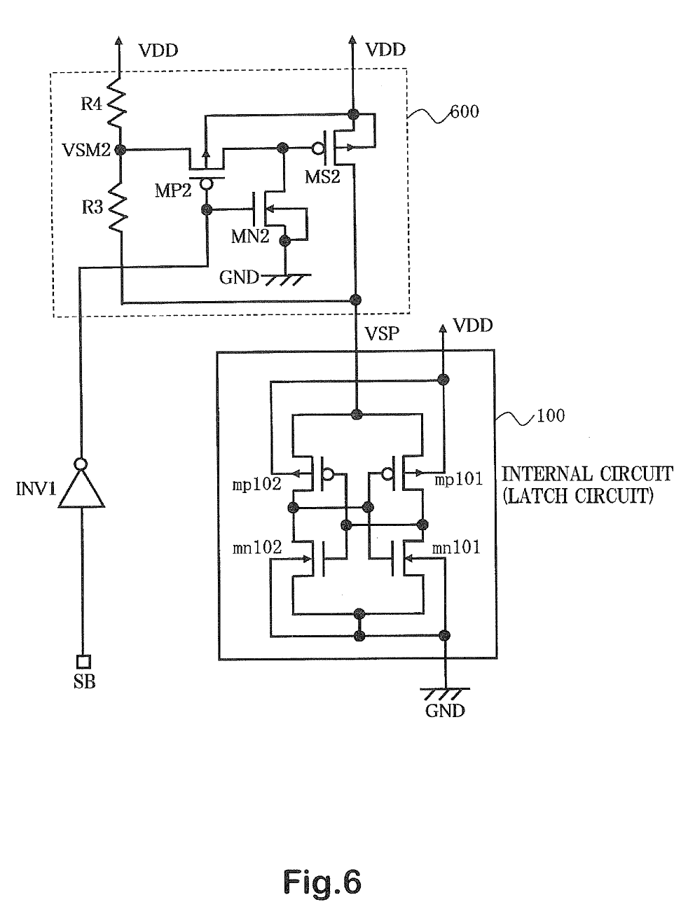

The sixth embodiment of the present invention provides an IC for effectively reducing the leakage current in an internal circuit and consumption current. FIG. 6 is an equivalent circuit schematic showing a configuration of an IC in accordance with the sixth embodiment of the present invention.

As shown in FIG. 6, the IC in accordance with the sixth embodiment of the present invention comprises an internal circuit 100, and a leakage current reducing circuit 600 that is electrically coupled between the internal circuit 100 and a VDD and which reduces the leakage current during the standby mode of the internal circuit 100.

The leakage current reducing circuit 600 is different from the leakage current reducing circuit 300 (see FIG. 2) in accordance with the above described second embodiment, in that a voltage divider is added to the leakage current reducing circuit 600. In short, a control circuit in the leakage current reducing circuit 600 is comprised of a fourth NMOS transistor MN2, a fourth PMOS transistor MP2, and a voltage divider comprised of a serial connection of a third resistance R3 and a fourth resistance R4. The voltage divider comprised of the serial connection of the third resistance R3 and the fourth resistance R4 is coupled between a high side node VSP and a VDD, and a divided voltage determined by the ratio of the third resistance R3 to the fourth resistance R4 will arise in a node VSM2 between the third resistance R3 and the fourth resistance R4. The source of the fourth PMOS transistor MP2 is coupled to the node VSM2 of the voltage divider.

This voltage divider is configured for a case in which the size of the second PMOS switching transistor MS2 in accordance with the above described second embodiment is limited by the properties of the internal circuit during the operation mode. In other words, the potential of the high side node VSP is determined by the size and the leakage current of the internal circuit 100 during the standby mode. Therefore, it may be difficult for the potential of the high side node VSP to be set to an arbitrary value. Consequently, as shown in FIG. 6, the voltage divider that is comprised of the serial connection of the third resistance R3 and the fourth resistance R4, which is disposed between the high side node VSP and the VDD, is provided, and thus the gate potential of the second PMOS switching transistor MS2 is controlled by means of the potential that is determined by the ratio of the voltage derived by the ratio of the third resistance R3 to the fourth resistance R4 and will arise in the node VSM2.

The operation of the IC in accordance with the present invention will be hereinafter explained.

During the operation mode of the internal circuit 100, a low-level signal Low is output from the standby signal terminal SB, and a high-level signal High, that is, an inversion signal of the standby signal terminal SB, is input into the leakage current reducing circuit 600. As a result, the fourth NMOS transistor MN2 is turned on and the fourth PMOS transistor MP2 is turned off. In addition, the gate potential of the second PMOS switching transistor MS2 will become the same level as the GND, and the second PMOS switching transistor MS2 is turned on. Because of this, the high side node VSP is coupled to the VDD with a low impedance. Therefore, the internal circuit 100 normally operates.

During the standby mode of the internal circuit 100, a high-level signal High is output from the standby signal terminal SB, and a low-level signal Low, that is, an inversion signal of the standby signal terminal SB, is input into the leakage current reducing circuit 600. The fourth PMOS transistor MP2 is turned on and the fourth NMOS transistor MN2 is turned off. Then, the gate of the second PMOS switching transistor MS2 is coupled to a potential that is determined by the ratio of the voltage derived by the ratio of the third resistance R3 to the fourth resistance R4 and will arise in the node VSM2. The second PMOS switching transistor MS2 uses the leakage current of the internal circuit 100 during the standby mode as a bias current and operates as with a MOS diode. The second PMOS switching transistor MS2 retains a potential of the high side node VSP at a constant potential that is lower than the VDD. The body potentials of first and second PMOS transistors mp101 and mp102 in the internal circuit 100 are coupled to the VDD. Therefore, the leakage current of the first and second PMOS transistors mp101 and mp102 are reduced by means of the reverse bias effect between the source and the body. In addition, the source-to-drain voltage further decreases by means of a bias applied to the high side node VSP, compared to a case in which the high side node VSP is coupled to the VDD. Accordingly, the leakage current of the first and second NMOS transistors mn101 and mn102 will be reduced.

As described above, according to the sixth embodiment of the present invention, the voltage divider that is comprised of the serial connection of the third resistance R3 and the fourth resistance R4, which is coupled between the high side node VSP and the VDD, is provided, and thus the gate potential of the second PMOS switching transistor MS2 is controlled by means of a potential that is determined by the ratio of the voltage derived by the ratio of the third resistance R3 to the fourth resistance R4 and will arise in the node VSM2.

With this configuration, it is possible to adjust the potential of the high side node VSP by adjusting the ratio of the third resistance R3 to the fourth resistance R4.

In addition, a corrective effect can be obtained in which the source bias voltage will be higher on condition that the leakage current of the internal circuit 100 is large, and the source bias voltage will be lower on condition that the leakage current of the internal circuit 100 is small, by controlling the gate potential of the second PMOS switching transistor MS2 by means of the ratio of the third resistance R3 to the fourth resistance R4. The condition that the leakage current is small is one in which the threshold voltage of the MOS transistor in the internal circuit 100 is large. Therefore, the condition will be one in which the minimum operation voltage necessary for ensuring a data retaining operation by the internal circuit during the standby mode is high. Because of this, when the bias current is small, the condition that the bias voltage is small has the effect of enhancing noise resistance in the data retaining operation.

### Seventh Embodiment

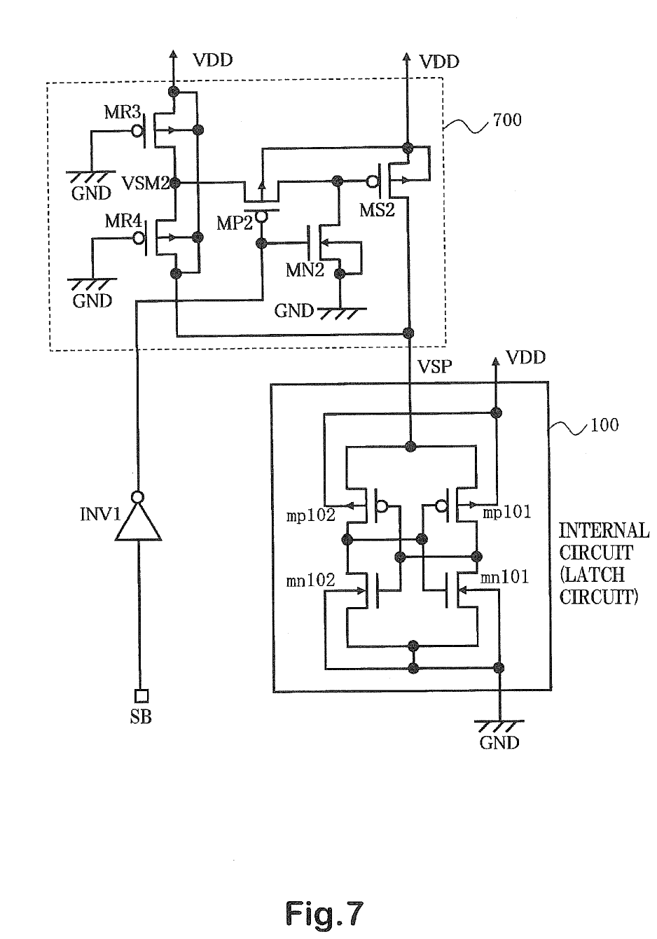

The seventh embodiment of the present invention provides an IC for effectively reducing the leakage current in an internal circuit and consumption current. FIG. 7 is an equivalent circuit schematic showing a configuration of an IC in accordance with the seventh embodiment of the present invention.

As shown in FIG. 7, the IC in accordance with the seventh embodiment of the present invention comprises an internal circuit 100, and a leakage current reducing circuit 700 that is electrically coupled between the internal circuit 100 and a VDD and which reduces the leakage current during the standby mode of the internal circuit 100.

The leakage current reducing circuit 700 is different from the leakage current reducing circuit 600 in accordance with the sixth embodiment in that a fifth PMOS transistor MR3 that is always in the on-state and a sixth PMOS transistor MR4 that is always in the on-state are used in the leakage current reducing circuit 700 instead of using the third resistance R3 and the fourth resistance R4, both of which are used in the leakage current reducing circuit 600. Other configurations of the leakage current reducing circuit 700 are the same as those of the leakage current reducing circuit 600.

As shown in FIG. 7, a voltage divider comprised of a serial connection of the fifth PMOS transistor MR3 that is always in the on-state and the sixth PMOS transistor MR4 that is always in the on-state is coupled between a high side node VSP and a VDD, and divided voltage determined by the ratio of a third on-resistance of the fifth PMOS transistor MR3 to a fourth on-resistance of the sixth PMOS transistor MR4 will arise in a node VSM2 between the fifth PMOS transistor MR3 and the sixth PMOS transistor MR4. Here, the gate of the fifth PMOS transistor MR3 may be coupled to a GND so as to keep the fifth PMOS transistor MR3 to be always in the on-state. In the same way, the gate of the sixth PMOS transistor MR4 may be coupled to the GND so as to keep the sixth PMOS transistor MR4 to be always in the on-state.

This voltage divider is configured for a case in which the size of the second PMOS switching transistor MS2 is limited by the properties of the internal circuit during the operation mode as with the above described sixth embodiment.

Therefore, the operation associated with the voltage divider in the IC in accordance with the present embodiment is the same as that in accordance with the fourth embodiment. Therefore, the operation of the IC in accordance with the present embodiment will be hereinafter omitted. With the seventh embodiment of the present invention, the same effects as those in accordance with the sixth embodiment can be obtained.

### Eighth Embodiment

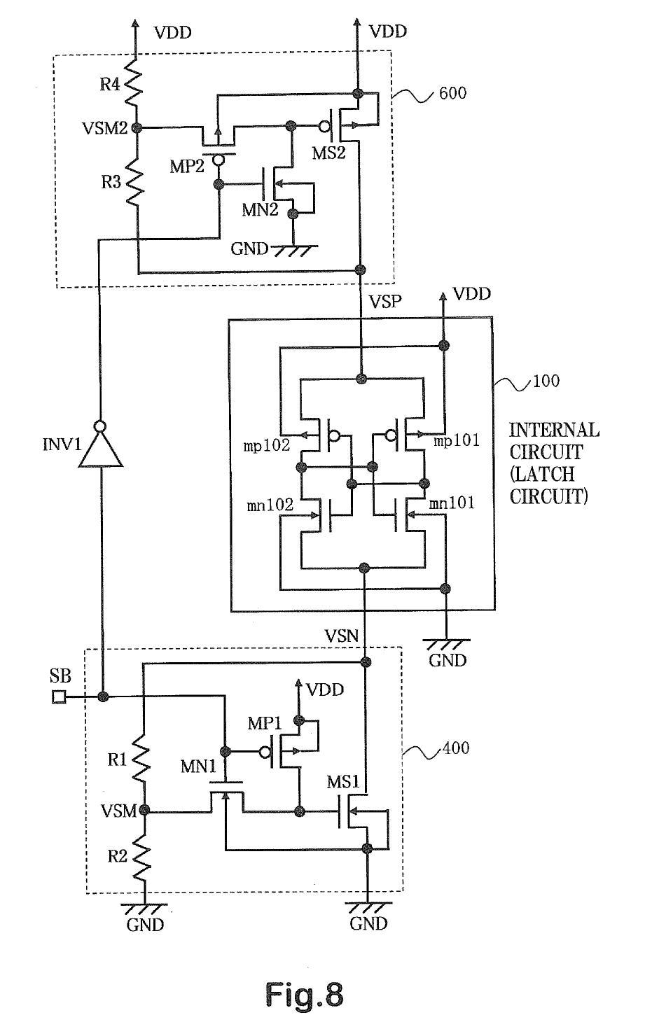

The eighth embodiment of the present invention provides an IC for effectively reducing the leakage current in an internal circuit and consumption current. FIG. 8 is an equivalent circuit schematic showing a configuration of an IC in accordance with the eighth embodiment of the present invention.

As shown in FIG. 8, the IC in accordance with the eighth embodiment of the present invention comprises an internal circuit 100, a leakage current reducing circuit 400 that is electrically coupled between the internal circuit 100 and a GND and which reduces the leakage current during the standby mode of the internal circuit 100, and a leakage current reducing circuit 600 that is electrically coupled between the internal circuit 100 and a VDD and which reduces the leakage current during the standby mode of the internal circuit 100.

In the present embodiment, the operation of the leakage current reducing circuit during the operation mode and the standby mode of the internal circuit 100 is the same as those in accordance with the above described fourth and sixth embodiments. Therefore, overlapping explanation will be hereinafter omitted. With the circuit configuration in accordance with the present embodiment, the same effects as those in accordance with the above described respective embodiments can be obtained.

### Ninth Embodiment

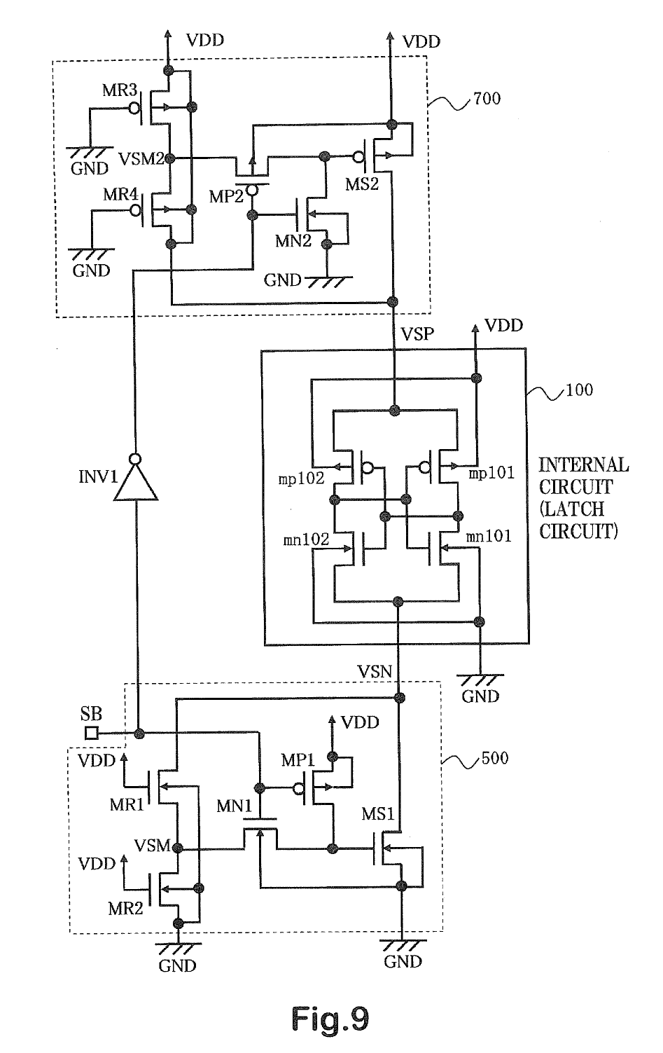

The ninth embodiment of the present invention provides an IC for effectively reducing the leakage current in an internal circuit and consumption current. FIG. 9 is an equivalent circuit schematic showing a configuration of an IC in accordance with the ninth embodiment of the present invention.

As shown in FIG. 9, the IC in accordance with the ninth embodiment of the present invention comprises an internal circuit 100, a leakage current reducing circuit 500 that is electrically coupled between the internal circuit 100 and a GND and which reduces the leakage current during the standby mode of the internal circuit 100, and a leakage current reducing circuit 700 that is electrically coupled between the internal circuit 100 and a VDD and which reduces the leakage current during the standby mode of the internal circuit 100.

In the present embodiment, the operation of the leakage current reducing circuit during the operation mode and the standby mode of the internal circuit 100 is the same as those in accordance with the above described fifth and seventh embodiments. Therefore, overlapping explanation will be hereinafter omitted. With the circuit configuration in accordance with the present embodiment, the same effects as those in accordance with the above described respective embodiments can be obtained.

### Tenth Embodiment

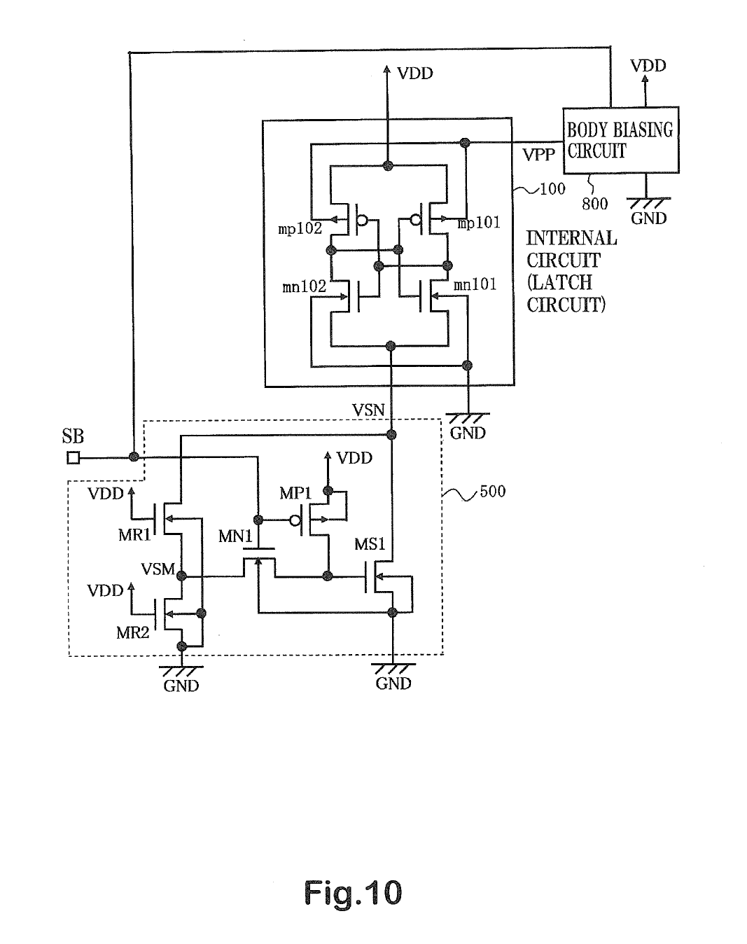

The tenth embodiment of the present invention provides an IC for effectively reducing the leakage current in an internal circuit and consumption current. FIG. 10 is an equivalent circuit schematic showing a configuration of an IC in accordance with the tenth embodiment of the present invention.

As shown in FIG. 10, the IC in accordance with the tenth embodiment of the present invention comprises an internal circuit 100, a leakage current reducing circuit 500 that is electrically coupled between the internal circuit 100 and a GND and which reduces the leakage current during the standby mode of the internal circuit 100, and a body biasing circuit 800 that is electrically coupled to the internal circuit 100 and controls a body potential of PMOS transistors included in the internal circuit 100. The output VPP of the body biasing circuit 800 is electrically coupled to the bodies of PMOS transistors included in the internal circuit 100. The body biasing circuit 800 can be realized by a heretofore known circuit configuration. For example, the body biasing circuit 800 can be configured by a heretofore known circuit comprised of a ring oscillator and a charge pump circuit.

In the circuit configuration shown in FIG. 5, the sources of the first and second NMOS transistors mn101 and mn102 in the internal circuit 100 are coupled to the low side node VSN and thus the sources are biased by means of the leakage current reducing circuit 500. Because of this, the body biasing effect arises only in the first and second NMOS transistors mn101 and mn102 in the internal circuit. Voltage applied to the both ends of the first and second PMOS transistors mp101 and mp102 in the internal circuit 100 will decrease by means of this source bias. Even though the leakage current of the first and second PMOS transistors mp101 and mp102 will decrease to some extent by means of this voltage reduction, this reduction is much smaller than the leakage current reduction by the body biasing effect. If the internal circuit 100 is comprised of a single or plurality of NMOS transistor(s) and a single or plurality of PMOS transistor(s) and the number of the NMOS transistor(s) and that of the PMOS transistor(s) are the same, it is required to reduce a single or plurality of figure(s) of the leakage current of the NMOS transistor(s), and at the same time as this, it is also required to reduce a single or plurality of figure(s) of the leakage current of the PMOS transistor(s) so as to reduce a single or plurality of figure(s) of the entire leakage current of the internal circuit 100, for instance. For example, if the leakage current of the NMOS transistor(s) is only reduced, the theoretical maximum reduction ratio of the leakage current of the NMOS transistor(s) and that of the PMOS transistor(s) to the whole will be 50%. Therefore, in order to reduce the leakage current of the PMOS transistor(s), a method can be considered in which a source bias is applied not only to the NMOS transistor(s) but also to PMOS transistor(s) as with the above described third embodiment shown in FIG. 3.

However, in the present embodiment, a method is used in which a body biasing circuit 800 including an output VPP electrically coupled to PMOS transistor(s) included in the internal circuit 100 is provided instead of using the above considered method. In other words, the threshold voltages of the PMOS transistor(s) included in the internal circuit 100, specifically, those of the PMOS transistors mp101 and mp102 are controlled to be low during the operation mode and high during the standby mode by means of the body biasing circuit 800, and accordingly the leakage current of the PMOS transistors mp101 and mp102 during the standby mode is reduced, and furthermore, the leakage current of the entire internal circuit during the standby mode can be reduced. Therefore, the body biasing circuit 800 is coupled to a standby signal terminal SB, and recognizes if the internal circuit 100 is in the operation mode or in the standby mode based on the standby signal terminal SB. If the internal circuit 100 is in the operation mode, the body biasing circuit 800 outputs a voltage that is the same as or lower than VDD, and the threshold voltages of the PMOS transistors mp101 and mp102 are retained to be low. On the other hand, if the internal circuit 100 is in the standby mode, the body biasing circuit 800 outputs a body bias voltage VPP that is higher than VDD, and the threshold voltages of the PMOS transistors mp101 and mp102 are retained to be high.

The operation of the IC in accordance with the present invention will be hereinafter explained.

During the operation mode of the internal circuit 100, a low-level signal Low is output from the standby signal terminal SB, and the third NMOS transistor MN1 is turned off and the third PMOS transistor MP1 is turned on. In addition, the gate potential of the first NMOS switching transistor MS1 will become the same level as the VDD, and the first NMOS switching transistor MS1 is turned on. Because of this, the low side node VSN is coupled to the GND with a low impedance. Therefore, the internal circuit 100 normally operates. In the meantime, the body biasing circuit 800 outputs a voltage that is the same as or lower than VDD, and the threshold voltages of the PMOS transistors mp101 and mp102 are retained to be low.

During the standby mode of the internal circuit 100, a high-level signal High is output from the standby signal terminal SB, and the third PMOS transistor MP1 is turned off and the third NMOS transistor MN1 is turned on. In addition, the gate of the first NMOS switching transistor MS1 is coupled to a potential that is determined by the ratio of the voltage derived by the ratio of the first on-resistance of the fifth NMOS transistor MR1 to the second on-resistance of the sixth NMOS transistor MR2 and will arises in the node VSM. The first NMOS switching transistor MS1 uses the leakage current of the internal circuit 100 during the standby mode as a bias current and operates as with a MOS diode. The first NMOS switching transistor MS1 retains the potential of the low side node VSN at a constant potential that is higher than the GND. The body potentials of the first and second NMOS transistors mn101 and mn102 in the internal circuit 100 are coupled to the GND. Therefore, the leakage current of the first and second NMOS transistors mn101 and mn102 are reduced by means of the reverse bias effect between the source and the body. In addition, the source-to-drain voltage further decreases by means of a bias applied to the low side node VSN, compared to a case in which the low side node VSN is coupled to the GND. Accordingly, the leakage current of the first and second PMOS transistors mp101 and mp102 will be reduced. In the meantime, the body biasing circuit 800 outputs a body bias voltage VPP that is higher than VDD, and the threshold voltages of the PMOS transistors mp101 and mp102 are retained to be high. Therefore, the leakage current is further reduced.

As described above, according to the tenth embodiment of the present invention, the leakage current of both of the PMOS transistor(s) and the NMOS transistor(s) that comprise the internal circuit can be reduced during the standby mode by providing the body biasing circuit 800. Therefore, it is possible to further reduce the leakage current of the whole internal circuit 100 during the standby mode, compared to, for example, the circuit shown in FIG. 5. In addition, a source bias is only applied to the low potential side. Therefore, it is possible to reduce the leakage current while ensuring data retaining function of a latch circuit, even in the case of a low power supply voltage.

### Eleventh Embodiment

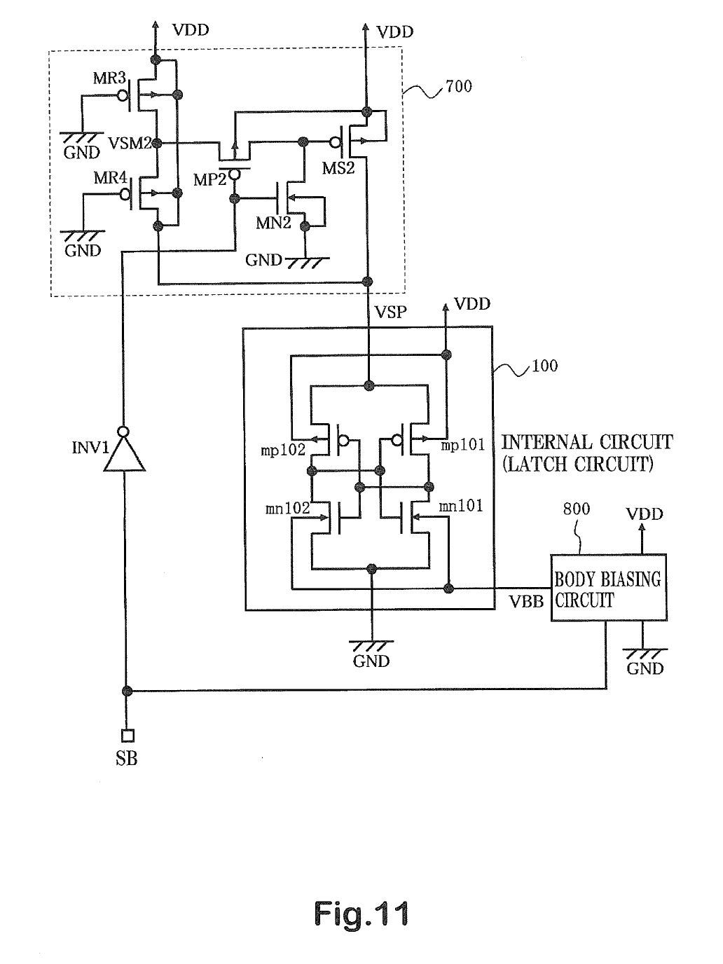

The eleventh embodiment of the present invention provides an IC for effectively reducing the leakage current in an internal circuit and consumption current. FIG. 11 is an equivalent circuit schematic showing a configuration of an IC in accordance with the eleventh embodiment of the present invention.

As shown in FIG. 11, the IC in accordance with the eleventh embodiment of the present invention comprises an internal circuit 100, a leakage current reducing circuit 700 that is electrically coupled between the internal circuit 100 and a VDD and which reduces the leakage current during the standby mode of the internal circuit 100, and a body biasing circuit 800 that is electrically coupled to the internal circuit 100 and controls the body potential of a NMOS transistor included in the internal circuit 100. An output VBB of the body biasing circuit 800 is electrically coupled to the bodies of NMOS transistors included in the internal circuit 100.

The IC shown in FIG. 10 is configured by providing the body biasing circuit 800 to the circuit shown in FIG. 5. In the same way, the IC in accordance with the present invention shown in FIG. 11 is configured by providing the body biasing circuit 800 to the circuit shown in FIG. 7. An object of providing the body biasing circuit 800 in the present embodiment is the same as that in the tenth embodiment.

In other words, it is an object of the present embodiment to reduce the leakage current of the NMOS transistors mn101 and mn102 during the standby mode, and furthermore, reduce the leakage current of the entire internal circuit during the standby mode, by controlling the threshold voltages of the NMOS transistor(s) included in the internal circuit 100, specifically, those of the NMOS transistors mn101 and mn102, so as to be low during the operation mode and high during the standby mode by means of the body biasing circuit 800. Therefore, the body biasing circuit 800 is coupled to a standby signal terminal SB, and recognizes if the internal circuit 100 is in the operation mode or in the standby mode based on the standby signal terminal SB. If the internal circuit 100 is in the operation mode, the body biasing circuit 800 outputs a voltage that is the same as or higher than GND, and the threshold voltages of the NMOS transistors mn101 and mn102 are retained to be low. On the other hand, if the internal circuit 100 is in the standby mode, the body biasing circuit 800 outputs a body bias voltage VBB that is lower than GND, and the threshold voltages of the NMOS transistors mn101 and mn102 are retained to be high.

The operation of the IC in accordance with the present embodiment will be hereinafter explained.

During the operation mode of the internal circuit 100, a low-level signal Low is output from the standby signal terminal SB, and a high-level signal High, that is, an inversion signal of the standby signal terminal SB, is input into the leakage current reducing circuit 700. As a result, the fourth NMOS transistor MN2 is turned on and the fourth PMOS transistor MP2 is turned off. In addition, the gate potential of the second PMOS switching transistor MS2 will become the same level as the GND, and the second PMOS switching transistor MS2 is turned on. Because of this, the high side node VSP is coupled to the VDD with a low impedance. Therefore, the internal circuit 100 normally operates. Meanwhile, the body biasing circuit 800 outputs a voltage that is the same as or higher than GND, and the threshold voltages of the NMOS transistors mn101 and mn102 are retained to be low.

During the standby mode of the internal circuit 100, a high-level signal High is output from the standby signal terminal SB, and a low-level signal Low, that is, an inversion signal of the standby signal terminal SB, is input into the leakage current reducing circuit 700. The fourth PMOS transistor MP2 is turned on and the fourth NMOS transistor MN2 is turned off. Then, the gate of the second PMOS switching transistor MS2 is coupled to a potential that is determined by the ratio of the voltage derived by the ratio of the third on-resistance to the fourth on-resistance and will arise in the node VSM2. The second PMOS switching transistor MS2 uses the leakage current of the internal circuit 100 during the standby mode as a bias current and operates as with a MOS diode. The second PMOS switching transistor MS2 retains the potential of the high side node VSP at a constant potential that is lower than the VDD. The body potentials of first and second PMOS transistors mp101 and mp102 in the internal circuit 100 are coupled to the VDD. Therefore, the leakage current of the first and second PMOS transistors mp101 and mp102 are reduced by means of the reverse bias effect between the source and the body. In addition, the source-to-drain voltage further decreases by means of a bias applied to the high side node VSP, compared to a case in which the high side node VSP is coupled to the VDD. Accordingly, the leakage current of the first and second NMOS transistors mn101 and mn102 will be reduced. In the meantime, the body biasing circuit 800 outputs a body bias voltage VBB that is lower than GND, and the threshold voltages of the NMOS transistors mn101 and mn102 are retained to be high. Therefore, the leakage current is further reduced.

As described above, according to the eleventh embodiment of the present invention, the leakage current of both of the PMOS transistor(s) and the NMOS transistor(s) that comprise the internal circuit can be reduced during the standby mode by providing the body biasing circuit 800. Therefore, it is possible to further reduce the leakage current of the whole internal circuit 100 during the standby mode. In addition, a source bias is only applied to the high potential side. Therefore, it is possible to reduce the leakage current while ensuring the data retaining function of a latch circuit, even in the case of the low power supply voltage.

### Twelfth Embodiment

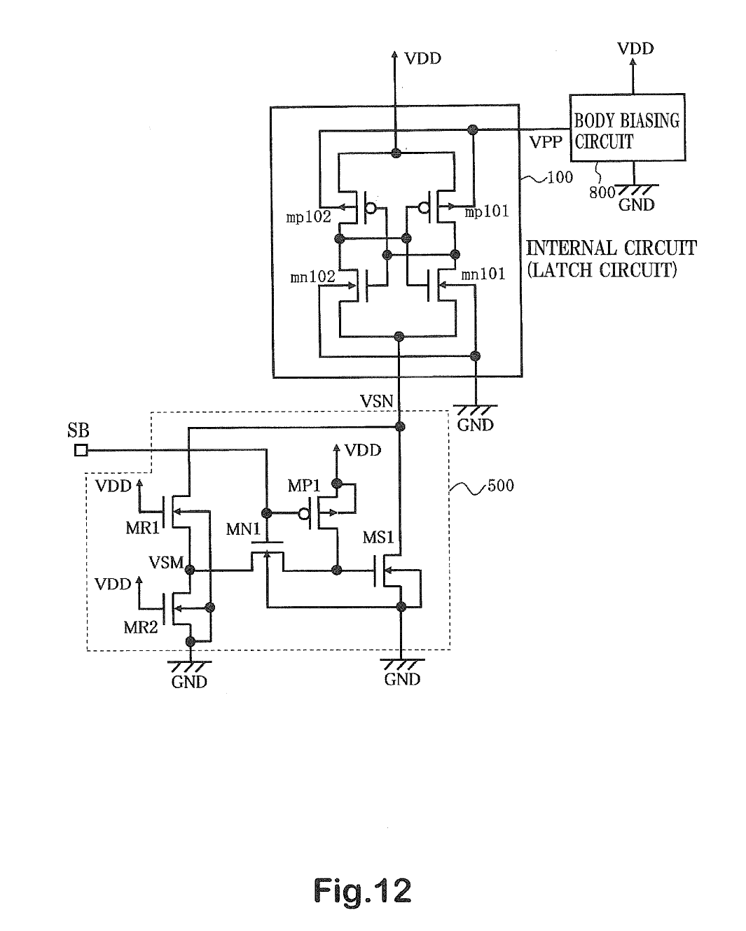

The twelfth embodiment of the present invention provides an IC for effectively reducing the leakage current in an internal circuit and consumption current. FIG. 12 is an equivalent circuit schematic showing a configuration of an IC in accordance with the twelfth embodiment of the present invention.

As shown in FIG. 12, the IC in accordance with the twelfth embodiment of the present invention comprises an internal circuit 100, a leakage current reducing circuit 500 that is electrically coupled between the internal circuit 100 and a GND and which reduces the leakage current during the standby mode of the internal circuit 100, and a body biasing circuit 800 that is electrically coupled to the internal circuit 100 and controls the body potential of a PMOS transistor included in the internal circuit 100. An output VPP of the body biasing circuit 800 is electrically coupled to bodies of PMOS transistors included in the internal circuit 100.

The IC in accordance with the present embodiment is different from the IC shown in FIG. 10 in that the body biasing circuit 800 outputs a body bias voltage VPP that is higher than VDD regardless of the state (operation mode or standby mode) of the internal circuit 100, and the threshold voltages of the PMOS transistors mp101 and mp102 are retained to be high.

In other words, the IC in accordance with the present embodiment has a configuration in which the body biasing circuit 800 is activated regardless of the state (operation mode or standby mode) of the internal circuit 100, and VPP is applied to the body of the PMOS transistors included in the internal circuit 100. Because of this, the threshold voltage of the PMOS transistors included in the internal circuit 100 will be high even during the operation mode. However, even in this case, this will be effective when transistor properties are not influenced thereby during the operation mode by performing a variety of measures such as increase of the gate width. In addition, it is possible to obtain a configuration in which a PMOS transistor with high threshold voltage is disposed without disposing the body biasing circuit 800.

The operation of the IC in accordance with the present embodiment will be hereinafter explained.

During the operation mode of the internal circuit 100, a low-level signal Low is output from the standby signal terminal SB, and the third NMOS transistor MN1 is turned off and the third PMOS transistor MP1 is turned on. In addition, the gate potential of the first NMOS switching transistor MS1 will become the same level as the VDD, and the first NMOS switching transistor MS1 is turned on. Because of this, the low side node VSN is coupled to the GND with a low impedance. Therefore, the internal circuit 100 normally operates. Meanwhile, the body biasing circuit 800 outputs a body bias voltage VPP that is higher than VDD, and the threshold voltages of the PMOS transistors mp101 and mp102 are retained to be high.

During the standby mode of the internal circuit 100, a high-level signal High is output from the standby signal terminal SB, and the third PMOS transistor MP1 is turned off and the third NMOS transistor MN1 is turned on. In addition, the gate of the first NMOS switching transistor MS1 is coupled to a potential that is determined by the ratio of the voltage derived by the ratio of the first on-resistance of the fifth NMOS transistor MR1 to the second on-resistance of the sixth NMOS transistor MR2 and will arise in the node VSM. The first NMOS switching transistor MS1 uses the leakage current of the internal circuit 100 during the standby mode as a bias current and operates as with a MOS diode. The first NMOS switching transistor MS1 retains a potential of the low side node VSN at a constant potential that is higher than the GND. The body potentials of the first and second NMOS transistors mn101 and mn102 in the internal circuit 100 are coupled to the GND. Therefore, the leakage current of the first and second NMOS transistors mn101 and mn102 are reduced by means of the reverse bias effect between the source and the body. In addition, the source-to-drain voltage further decreases by means of a bias applied to the low side node VSN, compared to a case in which the low side node VSN is coupled to the GND. Accordingly, the leakage current of the first and second PMOS transistors mp101 and mp102 will be reduced. Meanwhile, the body biasing circuit 800 outputs a body bias voltage VPP that is higher than VDD, and the threshold voltages of the PMOS transistors mp101 and mp102 are retained to be high.

As described above, according to the twelfth embodiment of the present invention, the leakage current of both of the PMOS transistor(s) and the NMOS transistor(s) that comprise the internal circuit can be reduced during the standby mode by providing the body biasing circuit 800. Therefore, it is possible to further reduce the leakage current of the whole internal circuit 100 during the standby mode. In addition, a source bias is only applied to the low potential side. Therefore, it is possible to reduce the leakage current while ensuring the data retaining function of a latch circuit, even in the case of the low power supply voltage.

Furthermore, the threshold voltage of the PMOS transistor included in the internal circuit 100 can be high even during the operation mode. Therefore, it is possible to reduce the leakage current that flows through the PMOS transistor even during the operation mode.

### Thirteenth Embodiment

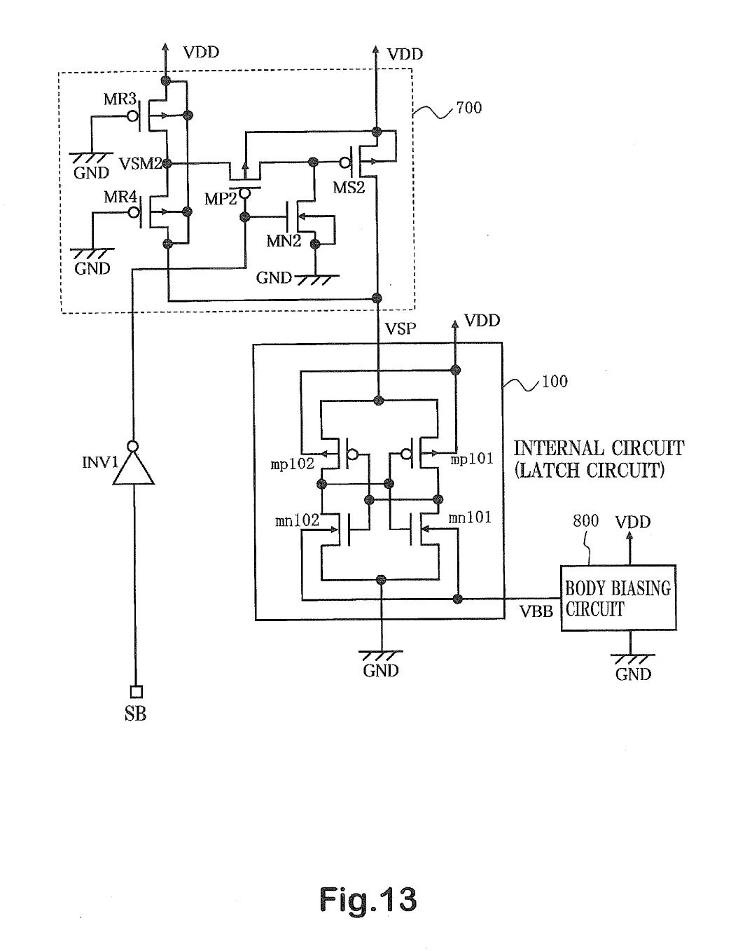

The thirteenth embodiment of the present invention provides an IC for effectively reducing the leakage current in an internal circuit and consumption current. FIG. 13 is an equivalent circuit schematic showing a configuration of an IC in accordance with the thirteenth embodiment of the present invention.

As shown in FIG. 13, the IC in accordance with the thirteenth embodiment of the present invention comprises an internal circuit 100, a leakage current reducing circuit 700 that is electrically coupled between the internal circuit 100 and a VDD and which reduces the leakage current during the standby mode of the internal circuit 100, and a body biasing circuit 800 that is electrically coupled to the internal circuit 100 and controls a body potential of a NMOS transistor included in the internal circuit 100. An output VBB of the body biasing circuit 800 is electrically coupled to bodies of NMOS transistors included in the internal circuit 100.

The IC in accordance with the present embodiment is different from the IC shown in FIG. 11 in that the body biasing circuit 800 outputs a body bias voltage VBB that is lower than GND regardless of the state (operation mode or standby mode) of the internal circuit 100, and the threshold voltages of the NMOS transistors mn101 and mn102 are retained to be high.

In other words, the IC in accordance with the present embodiment has a configuration in which the body biasing circuit 800 is activated regardless of the state (operation mode or standby mode) of the internal circuit 100 and VBB is applied to the bodies of the NMOS transistors included in the internal circuit 100. Because of this, the threshold voltage of the NMOS transistors included in the internal circuit 100 will be high even during the operation mode. However, even in this case, this will be effective when transistor properties are not influenced thereby during the operation mode by performing a variety of measures such as increase of the gate width. In addition, it is possible to obtain a configuration in which a NMOS transistor with high threshold voltage is disposed without disposing the body biasing circuit 800.

The operation of the IC in accordance with the present embodiment will be hereinafter explained.

During the operation mode of the internal circuit 100, a low-level signal Low is output from the standby signal terminal SB, and a high-level signal High, that is, an inversion signal of the standby signal terminal SB, is input into the leakage current reducing circuit 700. As a result, the fourth NMOS transistor MN2 is turned on and the fourth PMOS transistor MP2 is turned off. In addition, the gate potential of the second PMOS switching transistor MS2 will become the same level as the GND, and the second PMOS switching transistor MS2 is turned on. Because of this, the high side node VSP is coupled to the VDD with a low impedance. Therefore, the internal circuit 100 normally operates. Meanwhile, the body biasing circuit 800 outputs a body bias voltage VBB that is lower than GND, and the threshold voltages of the NMOS transistors mn101 and mn102 are retained to be high.

During the standby mode of the internal circuit 100, a high-level signal High is output from the standby signal terminal SB, and a low-level signal Low, that is, an inversion signal of the standby signal terminal SB, is input into the leakage current reducing circuit 700. The fourth PMOS transistor MP2 is turned on and the fourth NMOS transistor MN2 is turned off. Then, the gate of the second PMOS switching transistor MS2 is coupled to a potential that is determined by the ratio of the voltage derived by the ratio of the third on-resistance to the fourth on-resistance and will arise in the node VSM2. The second PMOS switching transistor MS2 uses the leakage current of the internal circuit 100 during the standby mode as a bias current and operates as with a MOS diode. The second PMOS switching transistor MS2 retains a potential of the high side node VSP at a constant potential that is lower than the VDD. The body potentials of first and second PMOS transistors mp101 and mp102 in the internal circuit 100 are coupled to the VDD. Therefore, the leakage current of the first and second PMOS transistors mp101 and mp102 are reduced by means of the reverse bias effect between the source and the body. In addition, the source-to-drain voltage further decreases by means of a bias applied to the high side node VSP, compared to a case in which the high side node VSP is coupled to the VDD. Accordingly, the leakage current of the first and second NMOS transistors mn101 and mn102 will be reduced. Meanwhile, the body biasing circuit 800 outputs a body bias voltage VBB that is lower than GND, and the threshold voltages of the NMOS transistors mn101 and mn102 are retained to be high.

As described above, according to the thirteenth embodiment of the present invention, the leakage current of both of the PMOS transistor(s) and the NMOS transistor(s) that comprise the internal circuit can be reduced during the standby mode by providing the body biasing circuit 800. Therefore, it is possible to further reduce the leakage current of the entire internal circuit 100 during the standby mode. In addition, a source bias is only applied to the high potential side. Therefore, it is possible to reduce the leakage current while ensuring the data retaining function of a latch circuit, even in the case of the low power supply voltage.

Furthermore, the threshold voltage of the NMOS transistor included in the internal circuit 100 can be high even during the operation mode. Therefore, it is possible to reduce the leakage current that flows through the NMOS transistor even during the operation mode.

### Fourteenth Embodiment

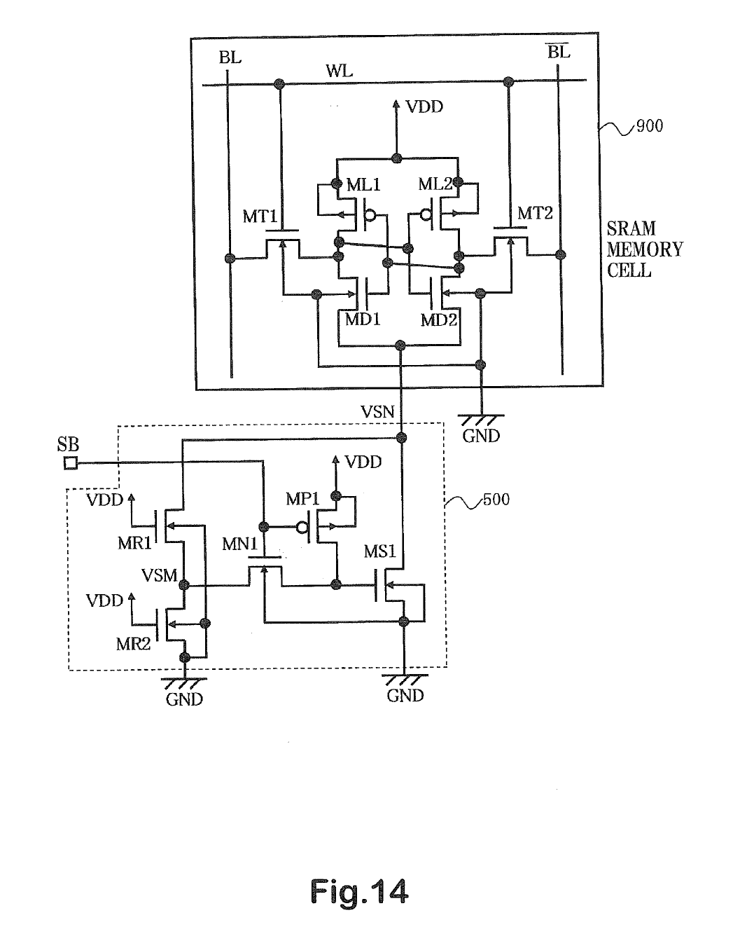

The fourteenth embodiment of the present invention provides an IC for effectively reducing the leakage current in an internal circuit and consumption current. FIG. 14 is an equivalent circuit schematic showing a configuration of an IC in accordance with the fourteenth embodiment of the present invention.

As shown in FIG. 14, the IC in accordance with the fourteenth embodiment of the present invention comprises a SRAM memory cell 900 functioning as an internal circuit, and a leakage current reducing circuit 500 that is electrically coupled between the SRAM memory cell 900 and a GND and which reduces the leakage current during the standby mode of the SRAM memory cell 900. In the above described first to thirteenth embodiments, a latch circuit is explained as an example of the internal circuit. However, in the present embodiment, a SRAM memory cell is used as an example of the internal circuit instead of using the latch circuit. In reference to FIG. 14, an example to which the above described leakage current reducing circuit is applied will be hereinafter explained.

As shown in FIG. 14, the SRAM memory cell 900 can be comprised of six MOS transistors. Specifically, each SRAM memory cell 900 comprises a first load PMOS transistor ML1, a second load PMOS transistor ML2, a first driving NMOS transistor MD1, a second driving NMOS transistor MD2, a first transfer NMOS transistor MT1, and a second transfer NMOS transistor MT2.

The first load PMOS transistor ML1 and the first driving NMOS transistor MD1 are serially coupled between VDD and a low side node VSN. The second load PMOS transistor ML2 and the second driving NMOS transistor MD2 are serially coupled between VDD and a low side node VSN.

A source of the first PMOS transistor ML1 is coupled to a VDD. A drain of the first load PMOS transistor ML1 is coupled to that of the first driving NMOS transistor MD1 and that of the first transfer NMOS transistor MT1. In addition, it is coupled to the gate of the second load PMOS transistor ML2 and that of the second driving NMOS transistor MD2. A source of the first NMOS transistor MD1 is coupled to the low side node VSN.

A source of the second load PMOS transistor ML2 is coupled to the VDD. A drain of the second load PMOS transistor ML2 is coupled to that of the second driving NMOS transistor MD2 and that of the second transfer NMOS transistor MT2. In addition, it is coupled to the gate of the first load PMOS transistor ML1 and that of the first driving NMOS transistor MD1. A source of the second driving NMOS transistor MD2 is coupled to the low side node VSN.

A drain of the first transfer NMOS transistor MT1 is coupled to that of the first load PMOS transistor ML1, that of the first driving NMOS transistor MD1, the gate of the second load PMOS transistor ML2, and that of the second driving NMOS transistor MD2. A source of the first transfer NMOS transistor MT1 is coupled to a non-inverted bit line BL. The gate of the first transfer NMOS transistor MT1 is coupled to a word line VL.

A drain of the second transfer NMOS transistor MT2 is coupled to that of the second load PMOS transistor ML2, that of the second driving NMOS transistor MD2, the gate of the first load PMOS transistor ML1, and that of the first driving NMOS transistor MD1. A source of the second transfer NMOS transistor MT2 is coupled to an inverted bit line/BL. The gate of the second transfer NMOS transistor MT2 is coupled to a word line WL.

A body of the first load PMOS transistor ML1 and that of the second load PMOS transistor ML2 are coupled to the VDD. A body of the first driving NMOS transistor MD1, that of the second driving NMOS transistor MD2, that of the first transfer NMOS transistor MT1, and that of the second transfer NMOS transistor MT2 are coupled to the GND. In other words, VDD is supplied to the body of the first load PMOS transistor ML1 and that of the second load PMOS transistor ML2. GND is supplied to the body of the first driving NMOS transistor MD1, that of the second driving NMOS transistor MD2, that of the first transfer NMOS transistor MT1, and that of the second transfer NMOS transistor MT2.

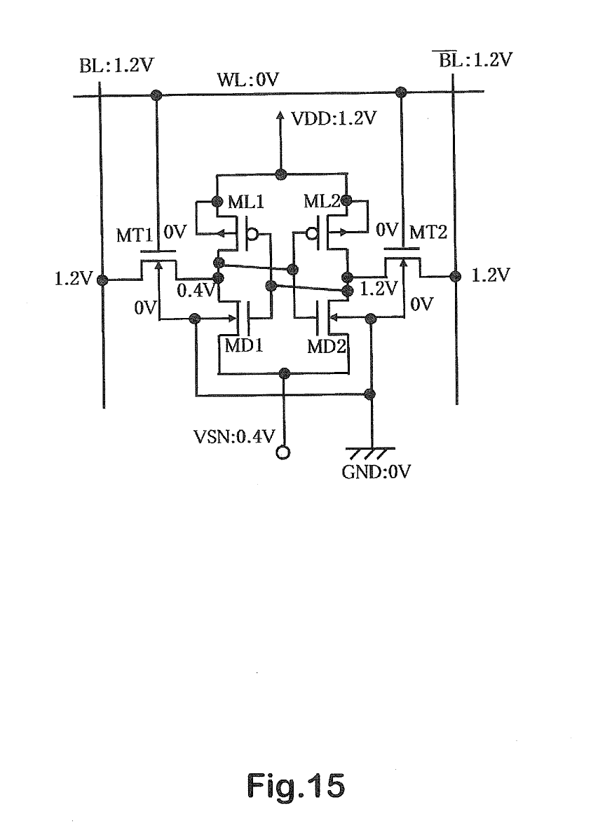

In the SRAM memory cell comprised of six transistors, four of the six transistors are NMOS transistors. Therefore, as shown in FIG. 15, it is possible to reduce relatively large amount of the leakage current of the whole SRAM memory cell even if the SRAM memory cell employs a source bias type in which source bias is applied on the VSN side. FIG. 15 is a schematic showing potentials of nodes in the SRAM memory cell shown in FIG. 14. FIG. 15 shows potentials of nodes in the SRAM memory cell on the standby mode under the following conditions. That is, VDD is set to be 1.2V, and the low side source bias voltage VSN is set to be 0.4V In the standby mode of the SRAM memory cell 900, the word line WL will be 0 V, and the non-inverted bit line BL and the inverted bit line/BL are coupled to VDD that is set to be 1.2 V. If a source bias is applied to the low side node VSN in the potential state shown in FIG. 15, the leakage current of the SRAM memory cell 900 on the standby mode and that of the driving transistor will be reduced by body biasing effect, and the leakage current of the load PMOS transistor will be reduced by voltage reduction between a source and a drain. Furthermore, the leakage current that flows through the transfer transistor is greatly reduced by the reverse bias effect between a source and a drain. Therefore, the leakage current in the whole memory cell is further reduced compared to a case in which a source bias is applied to a low potential side in a simple logic circuit or a latch circuit.

The operation of the IC in accordance with the present embodiment will be hereinafter explained.

During the operation mode of the SRAM memory cell 900, a low-level signal Low is output from the standby signal terminal SB, and the third NMOS transistor MN1 is turned off and the third PMOS transistor MP1 is turned on. In addition, the gate potential of the first NMOS switching transistor MS1 will become the same level as the VDD, and the first NMOS switching transistor MS1 is turned on. Because of this, the low side node VSN is coupled to the GND with a low impedance. Therefore, the SRAM memory cell 900 normally operates.

During the standby mode of the SRAM memory cell 900, a high-level signal High is output from the standby signal terminal SB, and the third PMOS transistor MP1 is turned off and the third NMOS transistor MN1 is turned on. In addition, the gate of the first NMOS switching transistor MS1 is coupled to a potential that is determined by the ratio of voltage dividing derived by the ratio of the first on-resistance of the fifth NMOS transistor MR1 to the second on-resistance of the sixth NMOS transistor MR2 and will arise in the node VSM. The first NMOS switching transistor MS1 uses the leakage current of the SRAM memory cell 900 during the standby mode as a bias current and operates as with a MOS diode. The first NMOS switching transistor MS1 retains a potential of the low side node VSN at a constant potential that is higher than the GND. The body potentials of the first and second driving NMOS transistors MD1 and MD2 in the SRAM memory cell 900 are coupled to the GND. Therefore, the leakage current of the first and second driving NMOS transistors MD1 and MD2 are reduced by means of the reverse bias effect between the source and the body. In addition, the source-to-drain voltage further decreases by means of a bias applied to the low side node VSN, compared to a case in which the low side node VSN is coupled to the GND. Accordingly, the leakage current of the first and second load PMOS transistors ML1 and ML2 will be reduced. Furthermore, a bias is applied to the low side node VSN. Therefore, the leakage current that flows through the first and second transfer NMOS transistors MT1 and MT2 will be also reduced because of the reverse bias effect between the gate and a source in the first and second transfer NMOS transistors MT1 and MT2.

As described above, according to the fourteenth embodiment of the present invention, source bias is applied on the low potential side of the memory cell. Therefore, it is possible to obtain highly effective leakage reduction effect. In other words, if a source bias is applied to the low side node VSN, the leakage current of the SRAM memory cell on the standby mode and the leakage current of the driving transistor will be reduced by body biasing effect, and the leakage current of the load PMOS transistor will be reduced by voltage reduction between a source and a drain. Furthermore, the leakage current that flows through the transfer transistor is greatly reduced by the reverse bias effect between a source and a drain. Therefore, the leakage current in the whole memory cell is further reduced compared to a case in which a source bias is applied to a low potential side in a simple logic circuit or a latch circuit.

### Fifteenth Embodiment

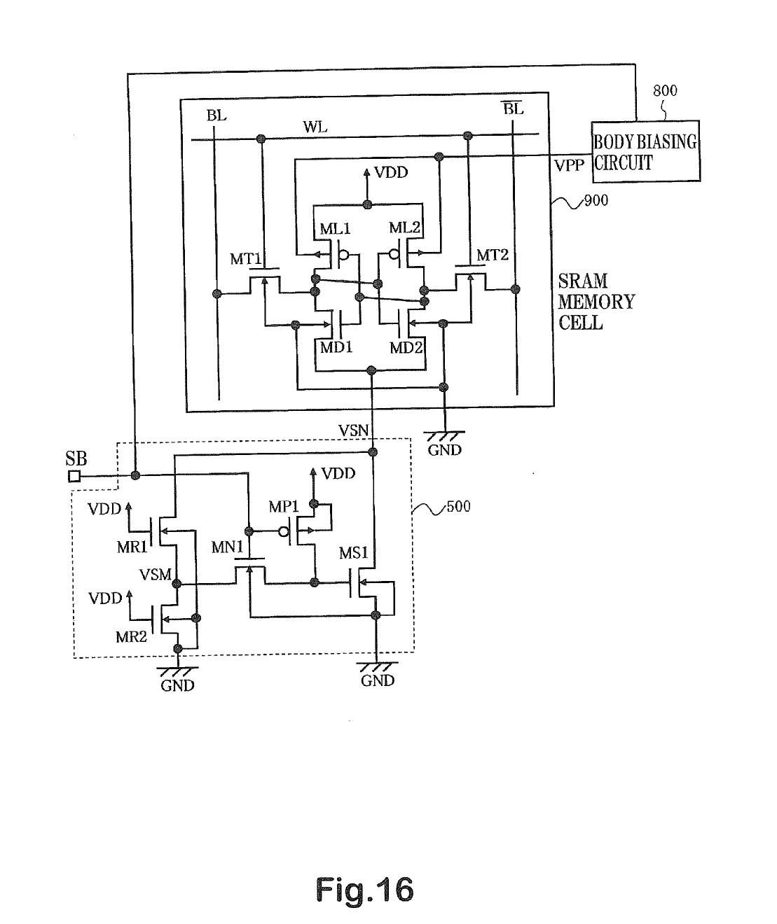

The fifteenth embodiment of the present invention provides an IC for effectively reducing the leakage current in an internal circuit and consumption current. FIG. 16 is an equivalent circuit schematic showing a configuration of an IC in accordance with the fifteenth embodiment of the present invention.

As shown in FIG. 16, the IC in accordance with the fifteenth embodiment of the present invention comprises a SRAM memory cell 900 functioning as an internal circuit, and a leakage current reducing circuit 500 that is electrically coupled between the SRAM memory cell 900 and a GND and which reduces the leakage current during the standby mode of the SRAM memory cell 900. The IC in accordance with the present embodiment is different from that shown in FIG. 14 in that a body biasing circuit is additionally provided to the IC in accordance with the present embodiment.

The body biasing circuit 800 includes an output VPP that is electrically coupled to bodies of a first load PMOS transistor ML1 and a second load PMOS transistor ML2, both of which are included in the SRAM memory cell 900. In other words, the threshold voltages of the first and second load PMOS transistors ML1 and ML2, both of which are included in the SRAM memory cell 900 are controlled to be low during the operation mode and high during the standby mode by means of the body biasing circuit 800, and accordingly the leakage current of the first and second load PMOS transistors ML1 and ML2 during the standby mode is reduced and furthermore the leakage current of the whole SRAM memory cell 900 during the standby mode can be reduced. Therefore, the body biasing circuit 800 is coupled to a standby signal terminal SB, and recognizes if the SRAM memory cell 900 is on the operation mode or on the standby mode based on the standby signal terminal SB. If the SRAM memory cell 900 is on the operation mode, the body biasing circuit 800 outputs a voltage that is the same as or lower than VDD, and the threshold voltages of the first and second load PMOS transistors ML1 and ML2 are retained to be low. On the other hand, if the SRAM memory cell is on the standby mode, the body biasing circuit 800 outputs a body bias voltage VPP that is higher than VDD, and the threshold voltages of the first and second load PMOS transistors ML1 and ML2 are retained to be high.

The operation of the IC in accordance with the present embodiment will be hereinafter explained.

During the operation mode of the SRAM memory cell 900, a low-level signal Low is output from the standby signal terminal SB, and the third NMOS transistor MN1 is turned off and the third PMOS transistor MP1 is turned on. In addition, the gate potential of the first NMOS switching transistor MS1 will become the same level as the VDD, and the first NMOS switching transistor MS1 is turned on. In addition, the body biasing circuit 800 outputs a voltage that is the same as or lower than VDD, and the threshold voltages of the first and second load PMOS transistors ML1 and ML2 are retained to be low. Because of this, a low side node VSN is coupled to the GND with a low impedance. Therefore, the SRAM memory cell 900 normally operates.

During the standby mode of the SRAM memory cell 900, a high-level signal High is output from the standby signal terminal SB, and the third PMOS transistor MP1 is turned off and the third NMOS transistor MN1 is turned on. In addition, the gate of the first NMOS switching transistor MS1 is coupled to a potential that is determined by the ratio of the voltage derived by the ratio of the first on-resistance of the fifth NMOS transistor MR1 to the second on-resistance of the sixth NMOS transistor MR2 and will arise in the node VSM. The first NMOS switching transistor MS1 uses the leakage current of the SRAM memory cell 900 during the standby mode as a bias current and operates as with a MOS diode. The first NMOS switching transistor MS1 retains a potential of the low side node VSN at a constant potential that is higher than the GND. The body potentials of first and second driving NMOS transistors MD1 and MD2 in the SRAM memory cell 900 are coupled to the GND. Therefore, the leakage current of the first and second driving NMOS transistors MD1 and MD2 are reduced by means of the reverse bias effect between the source and the body. In addition, the source-to-drain voltage further decreases by means of a bias applied to the low side node VSN, compared to a case in which the high side node VSP is coupled to the VDD. Accordingly, the leakage current of the first and second load PMOS transistors ML1 and ML2 will be reduced. The body biasing circuit 800 outputs a body bias voltage VPP that is higher than VDD, and the threshold voltages of the first and second load PMOS transistors ML1 and ML2 are retained to be high. Therefore, the leakage currents of the first and second load PMOS transistors ML1 and ML2 on the standby mode are further reduced. In addition, a bias is applied to the low side node VSN. Therefore, the leakage current that flows through the first and second transfer NMOS transistors MT1 and MT2 will be also reduced because of the reverse bias effect between the gate and the source in the first and second transfer NMOS transistors MT1 and MT2. Thus, the leakage current of the whole SRAM memory cell 900during the standby mode will be reduced.

As described above, according to the fifteenth embodiment of the present invention, the threshold voltages of the first and second load PMOS transistors ML1 and ML2 included in the SRAM memory cell 900 are controlled to be low during the operation mode and high during the standby mode by means of the body biasing circuit 800, and accordingly the leakage current of the first and second load PMOS transistors ML1 and ML2 during the standby mode is reduced and furthermore the leakage current of the whole SRAM memory cell 900 during the standby mode can be reduced. In other words, the leakage current of the load PMOS transistors during the standby mode can be reduced, and accordingly the leakage current of the whole SRAM memory cell 900 during the standby mode can be further reduced. In addition, source bias is only applied to the low potential side. Therefore, it is possible to reduce the leakage current while the data retaining function of a memory cell is ensured even in the case of the low power supply voltage.

### Sixteenth Embodiment

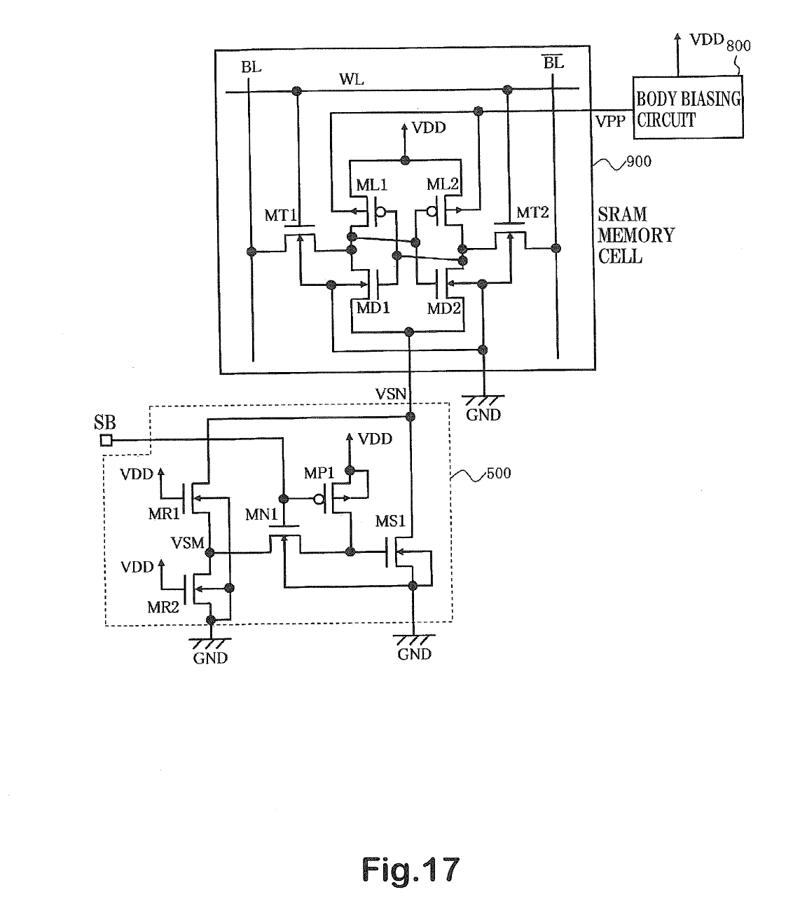

The sixteenth embodiment of the present invention provides an IC for effectively reducing the leakage current in an internal circuit and consumption current. FIG. 17 is an equivalent circuit schematic showing a configuration of an IC in accordance with the sixteenth embodiment of the present invention.

As shown in FIG. 17, the IC in accordance with the sixteenth embodiment of the present invention comprises a SRAM memory cell 900 functioning as an internal circuit, and a leakage current reducing circuit 500 that is electrically coupled between the SRAM memory cell 900 and a GND and which reduces the leakage current during the standby mode of the SRAM memory cell 900.

The IC in accordance with the present embodiment is different from the IC shown in FIG. 16 in that the body biasing circuit 800 outputs a body bias voltage VPP that is higher than VDD regardless of the state (operation mode or standby mode) of the internal circuit 900, and the threshold voltages of the first and second load PMOS transistors ML1 and ML2 are retained to be high.

In other words, the IC in accordance with the present embodiment has a configuration in which the body biasing circuit 800 is activated regardless of the state (operation mode or standby mode) of the SRAM memory cell 900 and VPP is applied to the bodies of the first and second PMOS transistors ML1 and ML2 included in the SRAM memory cell 900. Because of this, the threshold voltages of the first and second load PMOS transistors ML1 and ML2 included in the SRAM memory cell 900 will be high even during the operation mode. However, even in this case, this will be effective when transistor properties are not influenced thereby during the operation mode by performing a variety of measures such as increase of the gate width. In addition, it is possible to obtain a configuration in which the first and second load PMOS transistors ML1 and ML2 with high threshold voltage are disposed without disposing the body biasing circuit 800.

Operation of the IC in accordance with the present embodiment will be hereinafter explained.

During the operation mode of the SRAM memory cell 900, a low-level signal Low is output from the standby signal terminal SB, and the third NMOS transistor MN1 is turned off and the third PMOS transistor MP1 is turned on. In addition, the gate potential of the first NMOS switching transistor MS1 will become the same level as the VDD, and the first NMOS switching transistor MS1 is turned on. Because of this, the low side node VSN is coupled to the GND with a low impedance. Therefore, the SRAM memory cell 900 normally operates. Furthermore, the body biasing circuit 800 outputs a body bias voltage VPP that is higher than VDD, and the threshold voltages of the first and second load PMOS transistors ML1 and ML2 are retained to be high.

During the standby mode of the SRAM memory cell 900, a high-level signal High is output from the standby signal terminal SB, and the third PMOS transistor MP1 is turned off and the third NMOS transistor MN1 is turned on. In addition, the gate of the first NMOS switching transistor MS1 is coupled to a potential that is determined by the ratio of the voltage derived by the ratio of the first on-resistance of the fifth NMOS transistor MR1 to the second on-resistance of the sixth NMOS transistor MR2 and will arise in the node VSM. The first NMOS switching transistor MS1 uses the leakage current of the SRAM memory cell 900 during the standby mode as a bias current and operates as with a MOS diode. The first NMOS switching transistor MS1 retains a potential of the low side node VSN at a constant potential that is higher than the GND. The body potentials of the first and second driving NMOS transistors MD1 and MD2 in the SRAM memory cell 900 are coupled to the GND. Therefore, the leakage current of the first and second driving NMOS transistors MD1 and MD2 are reduced by means of the reverse bias effect between the source and the body. In addition, the source-to-drain voltage further decreases by means of a bias applied to the low side node VSN, compared to a case in which the low side node VSN is coupled to the GND. Accordingly, the leakage current of the first and second load PMOS transistors ML1 and ML2 will be reduced. The body biasing circuit 800 outputs a body bias voltage VPP that is higher than VDD, and the threshold voltages of the first and second load PMOS transistors ML1 and ML2 are retained to be high. Therefore, the leakage current of the first and second load PMOS transistors ML1 and ML2 during the standby mode is further reduced. In addition, a bias is applied to the low side node VSN. Therefore, the leakage current that flows through the first and second transfer NMOS transistors MT1 and MT2 will be also reduced because of the reverse bias effect between the gate and the source in the first and second transfer NMOS transistors MT1 and MT2. Thus, the leakage current of the whole SRAM memory cell 900 during the standby mode will be reduced.

As described above, according to the sixteenth embodiment of the present invention, the threshold voltages of the first and second load PMOS transistors ML1 and ML2 included in the SRAM memory cell 900 are controlled to be low during the operation mode and high during the standby mode by means of the body biasing circuit 800, and accordingly the leakage current of the first and second load PMOS transistors ML1 and ML2 during the standby mode is reduced and furthermore the leakage current of the whole SRAM memory cell 900 during the standby mode can be reduced. In other words, the leakage current of the load PMOS transistors during the standby mode can be reduced, and accordingly the leakage current of the whole SRAM memory cell 900 during the standby mode can be further reduced. In addition, source bias is only applied to the low potential side. Therefore, it is possible to reduce the leakage current while the data retaining function of a memory cell is ensured even in the case of the low power supply voltage.

### General Interpretation of Terms

In understanding the scope of the present invention, the term “configured” as used herein to describe a component, section or part of a device includes hardware and/or software that is constructed and/or programmed to carry out the desired function. In understanding the scope of the present invention, the term “comprising” and its derivatives, as used herein, are intended to be open ended terms that specify the presence of the stated features, elements, components, groups, integers, and/or steps, but do not exclude the presence of other unstated features, elements, components, groups, integers and/or steps. The foregoing also applied to words having similar meanings such as the terms, “including,” “having,” and their derivatives. Also, the term “part,” “section,” “portion,” “member,” or “element” when used in the singular can have the dual meaning of a single part or a plurality of parts. Finally, terms of degree such as “substantially,” “about,” and “approximately” as used herein mean a reasonable amount of deviation of the modified term such that the end result is not significantly changed. For example, these terms can be construed as including a deviation of at least ±5% of the modified term if this deviation would not negate the meaning of the word it modifies.

While only selected embodiments have been chosen to illustrate the present invention, it will be apparent to those skilled in the art from this disclosure that various changes and modifications can be made herein without departing from the scope of the invention as defined in the appended claims. Furthermore, the foregoing descriptions of the embodiments according to the present invention are provided for illustration only, and not for the purpose of limiting the invention as defined by the appended claims and their equivalents. Thus, the scope of the invention is not limited to the disclosed embodiments.

What is claimed is:

1. A semiconductor integrated circuit device, comprising:
a first circuit comprising a first field effect transistor; and
a second circuit that is electrically coupled to a source of the first field effect transistor and is configured to operate based on a first control signal representing an operation mode or a standby mode of the first circuit, and
wherein the second circuit is configured to apply a first source bias voltage to the first field effect transistor during the operation mode of the first circuit, the first source voltage not reversely biasing between the source and a body of the first field effect transistor; and the second circuit is configured to apply a second source bias voltage to the first field effect transistor during the standby mode of the first circuit, the second source bias voltage reversely biasing between the source and the body of the first field effect transistor.

2. The semiconductor integrated circuit device according to claim 1,
wherein the second circuit is electrically coupled between the source of the first field effect transistor and a first constant potential supply line configured to supply a first constant potential, the second circuit configured to apply the first constant potential to the source of the first field effect transistor as the first source bias voltage by coupling a source of the first field effect transistor to the first constant potential supply line during the operation mode of the first circuit; and configured to apply the second source bias voltage to the source of the first field effect transistor by decoupling the first field effect transistor from the first constant potential supply line during the standby mode of the first circuit.

3. The semiconductor integrated circuit device according to claim 2,
wherein the second circuit comprises:
a first switching transistor that is electrically coupled between the source of the first field effect transistor and the first constant potential supply line; and
a first control circuit that is electrically coupled to a gate of the first switching transistor;
the second circuit configured to apply the first constant potential to the source of the first field effect transistor as the first source bias voltage by placing the first switching transistor in a conductive state based on the first control signal during the operation mode of the first circuit; and apply a gate potential of the first switching transistor to the source of the first field effect transistor as the second source bias voltage by coupling the source of the first field effect transistor to the gate of the first switching transistor based on the first control signal during the standby mode of the first circuit.

4. The semiconductor integrated circuit device according to claim 3,
further comprising a first voltage divider that is electrically coupled between the source of the first field effect transistor and the first constant potential supply line;
the first voltage divider electrically coupled to the gate of the first switching transistor through the first control circuit; and
configured to retain the gate potential of the first switching transistor at a divided voltage potential between the source potential of the first field effect transistor and the first constant potential during the standby mode of the first circuit.

5. The semiconductor integrated circuit device according to claim 4, wherein the first voltage divider is comprised of a serial connection of a plurality of resistance elements.

6. The semiconductor integrated circuit device according to claim 4, wherein the first voltage divider is comprised of a serial connection of a plurality of on-resistances of the MOS transistors.

7. The semiconductor integrated circuit device according to claim 2,
wherein the first circuit is coupled to the first constant potential supply line and a second constant potential supply line for supplying a second constant potential that is lower than the first constant potential, the second source bias voltage being lower than the first source bias voltage.

8. The semiconductor integrated circuit device according to claim 7,
wherein the first constant potential supply line is a power supply potential supply line;
the second constant potential supply line is a ground potential supply line;
the first source bias voltage is set by the power supply potential; and
the second source bias voltage is set by a potential that is lower than the power supply potential.

9. The semiconductor integrated circuit device according to claim 2,
wherein the first circuit is coupled to the first constant potential supply line and a second constant potential supply line for supplying a second constant potential that is higher than the first constant potential; and
the second source bias voltage is higher than the first source bias voltage.

10. The semiconductor integrated circuit device according to claim 9,
wherein the first constant potential supply line is a ground potential supply line;
the second constant potential supply line is power supply potential supply line;
the first source bias voltage is set by the ground potential; and
the second source bias voltage is set by a potential that is higher than ground potential.

11. The semiconductor integrated circuit device according to claim 2, wherein the first circuit further comprises a second field effect transistor that is serially coupled to the first field effect transistor.

12. The semiconductor integrated circuit device according to claim 11,
further comprising a first body biasing circuit that is electrically coupled to a body of the second field effect transistor;
the first body biasing circuit configured to apply a first body bias voltage to the body of the second field effect transistor based on the first control signal only during the standby mode of the first circuit.

13. The semiconductor integrated circuit device according to claim 11,
further comprising a first body biasing circuit that is electrically coupled to a body of the second field effect transistor;
the first body biasing circuit configured to apply a first body bias voltage to the body of the second field effect transistor without depending on the first control signal during both the operation mode and the standby mode of the first circuit.

14. The semiconductor integrated circuit device according to claim 11,
further comprising a third circuit that is electrically coupled to a source of the second field effect transistor and configured to operate based on a second control signal representing the operation mode or the standby mode of the first circuit, the third circuit configured to apply a third source bias voltage, which does not reversely bias between a source and a body of the second field effect transistor, to the second field effect transistor during the operation mode of the first circuit; and configured to apply a fourth source bias voltage, which reversely biases between the source and the body of the second field effect transistor, to the second field effect transistor during the standby mode of the first circuit.

15. The semiconductor integrated circuit device according to claim 14,
wherein the third circuit is electrically coupled between the source of the second field effect transistor and a second constant potential supply line for supplying a second constant potential;
the third circuit configured to apply the second constant potential to the source of the second field effect transistor as the third source bias voltage by coupling a source of the second field effect transistor to the second constant potential supply line during the operation mode of the first circuit; and
apply the fourth source bias voltage to the source of the second field effect transistor by decoupling the second field effect transistor from the second constant potential supply line during the standby mode of the first circuit.

16. The semiconductor integrated circuit device according to claim 15,
wherein the third circuit comprises:
a second switching transistor that is electrically coupled between the source of the second field effect transistor and the second constant potential supply line; and
a second control circuit that is electrically coupled to a gate of the second switching transistor, the second control circuit configured to apply the second constant potential to the source of the second field effect transistor as the third source bias voltage by placing the second switching transistor in a conductive state based on the second control signal during the operation mode of the first circuit; and configured to apply a gate potential of the first switching transistor to the source of the second field effect transistor as the fourth source bias voltage by coupling the source of the first field effect transistor to the gate of the first switching transistor based on the second control signal during the standby mode of the first circuit.
